(19) United States
(12) Patent Application Publication
(10) Pub. No.: US 2021/0408298 A1
(43) Pub. Date: Dec. 30, 2021

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Erika TAKAHASHI, Chigasaki (JP); Hideomi SUZAWA, Atsugi (JP); Shinya SASAGAWA, Chigasaki (JP)

(21) Appl. No.: 17/295,693

(22) PCT Filed: Nov. 19, 2019
(86) PCT No.: PCT/IB2019/059911

§ 371 Date: May 20, 2021

(30) Foreign Application Priority Data
Nov. 30, 2018 (JP) 2018-224814

(51) Int. Cl. H01L 29/786

(52) U.S. Cl. CPC H01L 29/78684; H01L 29/78648

(57) ABSTRACT

A semiconductor device with high reliability is provided. A first conductor and a second conductor are provided over and in contact with a first oxide. A first insulator is provided to cover the first oxide, a first conductor, and a second conductor. The first insulator includes an opening portion. The first oxide is exposed on a bottom surface of the opening portion. A side surface of the first conductor and a side surface of the second conductor are exposed on a side surface of the opening portion. A second oxide is provided in contact with the first oxide, the side surface of the first conductor, and the second conductor in the opening portion. A second insulator is provided in the opening portion with the second oxide therebetween. A third conductor is provided in the opening portion with the second insulator therebetween. Lower end portions of the side surface of the first conductor and the second conductor touch an ellipse or a circle with a center above the first oxide.

### TECHNICAL FIELD

One embodiment of the present invention relates to a semiconductor device and a method for manufacturing the semiconductor device. Another embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a semiconductor thin film applicable to the transistor; in addition, an oxide semiconductor has been attracting attention as another material.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 disclose a technique for manufacturing a transistor using an oxide semiconductor having a CAAC structure.

[Non-Patent Document 1] S. Yamazaki et al., “SID Symposium Digest of Technical Papers”, 2012, volume 43, issue 1, p. 183-186
[Non-Patent Document 2] S. Yamazaki et al., “Japanese Journal of Applied Physics”, 2014, volume 53, Number 4S, p. 04ED18-1-04ED18-10

### Problems to be Solved by the Invention

### SUMMARY OF THE INVENTION

### Problems to be Solved by the Invention

An object of one embodiment of the present invention is to provide a semiconductor device with high reliability. Another object of one embodiment of the present invention is to provide a semiconductor device having favorable electrical characteristics. Another object of one embodiment of the present invention is to provide a semiconductor device with a high on-state current. Another object of one embodiment of the present invention is to provide a semiconductor device that can be miniaturized or highly integrated. Another object of one embodiment of the present invention is to provide a semiconductor device with low power consumption.

Note that the descriptions of these objects do not preclude the existence of other objects. One embodiment of the present invention does not need to achieve all of these objects. Objects other than these will be apparent from the descriptions of the specification, the drawings, the claims, and the like, and can be derived from the descriptions of the specification, the drawings, the claims, and the like.

### Means for Solving the Problems

One embodiment of the present invention is a semiconductor device including a first oxide, a second oxide, a first conductor, a second conductor, a third conductor, a first insulator, and a second insulator. The first conductor and the second conductor are provided over and in contact with the first oxide. The first insulator is provided to cover the first oxide, the first conductor, and the second conductor. The first insulator includes an opening portion. The first oxide is exposed on a bottom surface of the opening portion. A side surface of the first conductor and a side surface of the second conductor are exposed on a side surface of the opening portion. The second oxide is provided in contact with the first oxide, the side surface of the first conductor, and the second conductor in the opening portion. The second insulator is provided in the opening portion with the second oxide therebetween. The third conductor is provided in the opening portion with the second insulator therebetween. Lower end portions of the side surface of the first conductor and the second conductor touch an ellipse or a circle with a center above the first oxide.

One embodiment of the present invention is a semiconductor device including a first oxide, a second oxide, a first conductor, a second conductor, a third conductor, a first insulator, and a second insulator. The first conductor and the second conductor are provided over and in contact with the first oxide. The first insulator is provided to cover the first oxide, the first conductor, and the second conductor. The first insulator includes an opening portion. The first oxide is exposed on a bottom surface of the opening portion. A side surface of the first conductor and a side surface of the second conductor are exposed on a side surface of the opening portion. The second oxide is provided in contact with the first oxide, the side surface of the first conductor, and the second conductor in the opening portion. The second insulator is provided in the opening portion with the second oxide therebetween. The third conductor is provided in the opening portion with the second insulator therebetween. Lower end portions of the side surface of the first conductor and the second conductor each include a side surface like an arc with a curvature center above the first oxide. The length of a line perpendicular to the first oxide from the curvature center is substantially equal to the curvature radius of the arc.

In the above, a dihedral angle between a tangent plane touching the side surface like an arc at a termination portion of the side surface and a top surface of the first oxide is 0°<θ≤90°.

In the above, an upper end portion of the side surface of the first conductor and an upper end portion of the side surface of the second conductor are each substantially aligned with the tangent plane touching the side surface like an arc at the termination portion of the side surface.

In the above, the curvature radius is greater than or equal to a total of the thickness of the second oxide and the thickness of the second insulator.

In the above, the horizontal distance L between the curvature center and a side that is formed by a bottom surface of the third conductor and a side surface of the third conductor is less than or equal to 0.

In the above, the second oxide has a higher barrier property against oxygen than the second insulator.

In the above, the first oxide is an In—Ga—Zn oxide.

In the above, the second oxide is an In—Ga—Zn oxide.

### Effect of the Invention

According to one embodiment of the present invention, a semiconductor device with high reliability can be provided. According to another embodiment of the present invention, a semiconductor device having favorable electrical characteristics can be provided. According to another embodiment of the present invention, a semiconductor device with a high on-state current can be provided. According to another embodiment of the present invention, a semiconductor device that can be miniaturized or highly integrated can be provided. According to another embodiment of the present invention, a semiconductor device with low power consumption can be provided.

Note that the descriptions of the effects do not preclude the existence of other effects. One embodiment of the present invention does not necessarily achieve all the effects. Effects other than these will be apparent from the descriptions of the specification, the drawings, the claims, and the like, and can be derived from the descriptions of the specification, the drawings, the claims, and the like.

### BRIEF DESCRIPTION OF THE DRAWINGS

FIG. 1A and FIG. 1B are cross-sectional views of a semiconductor device of one embodiment of the present invention.

FIG. 2A, FIG. 2B, and FIG. 2C are top views of a semiconductor device of one embodiment of the present invention.

FIG. 3A, FIG. 3B, and FIG. 3C are a top view and cross-sectional views of a semiconductor device of one embodiment of the present invention.

FIG. 4A, FIG. 4B, and FIG. 4C are a top view and cross-sectional views of a semiconductor device of one embodiment of the present invention.

FIG. 5 is a cross-sectional view illustrating a structure of a memory device of one embodiment of the present invention.

FIG. 6 is a cross-sectional view illustrating a structure of a memory device of one embodiment of the present invention.

FIG. 7 is a cross-sectional view illustrating a structure of a memory device of one embodiment of the present invention.

FIG. 8A and FIG. 8B are a block diagram and a perspective view illustrating a structure example of a memory device of one embodiment of the present invention.

FIG. 9A, FIG. 9B, FIG. 9C, FIG. 9D, FIG. 9E, FIG. 9F, FIG. 9G, and FIG. 9H are circuit diagrams illustrating structure examples of a memory device of one embodiment of the present invention.

FIG. 10A and FIG. 10B are schematic diagrams of a semiconductor device of one embodiment of the present invention.

FIG. 11A, FIG. 11B, FIG. 11C, FIG. 11D, and FIG. 11E are schematic diagrams of a memory device of one embodiment of the present invention.

FIG. 12A, FIG. 12B, FIG. 12C, FIG. 12D, FIG. 12E, FIG. 12F, FIG. 12G, and FIG. 12H each illustrate an electronic device of one embodiment of the present invention.

FIG. 13 illustrates the thickness of an oxidized portion of a side end portion of a conductor according to Example.

### MODE FOR CARRYING OUT THE INVENTION

Hereinafter, embodiments will be described with reference to drawings. However, the embodiments can be implemented with many different modes, and it will be readily appreciated by those skilled in the art that modes and details thereof can be changed in various ways without departing from the spirit and scope thereof. Thus, the present invention should not be interpreted as being limited to the following descriptions of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding of the invention. Furthermore, in the drawings, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. The description of some hidden lines and the like might also be omitted.

Note that in this specification and the like, the ordinal numbers such as first and second are used for convenience and do not denote the order of steps or the stacking order of layers. Therefore, for example, description can be made even when “first” is replaced with “second”, “third”, or the like, as appropriate. In addition, the ordinal numbers in this specification and the like do not correspond to the ordinal numbers which are used to specify one embodiment of the present invention in some cases.

In this specification and the like, terms for describing arrangement, such as “over” and “under”, are used for convenience in describing a positional relation between components with reference to drawings. Furthermore, the positional relation between components is changed as appropriate in accordance with a direction in which each component is described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals of a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or a direction of current flow is changed in circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, a length of a channel formation region in a direction perpendicular to a channel length direction in a region where a semiconductor (or a portion where current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an effective channel width) is sometimes different from a channel width shown in a top view of a transistor (hereinafter also referred to as an apparent channel width). For example, when a gate electrode covers a side surface of a semiconductor, an effective channel width is larger than an apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to apparent channel width in some cases. Alternatively, in this specification, the simple term “channel width” refers to effective channel width in some cases. Note that values of channel length, channel width, effective channel width, apparent channel width, and the like can be determined, for example, by analyzing a cross-sectional TEM image and the like.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, transition metals other than the main components of the oxide semiconductor, and the like; hydrogen, lithium, sodium, silicon, boron, phosphorus, carbon, nitrogen, and the like are given as examples. Note that water also serves as an impurity in some cases. Entry of an impurity may cause oxygen vacancies in an oxide semiconductor, for example.

Note that in this specification and the like, silicon oxynitride is a material that contains more oxygen than nitrogen in its composition. Moreover, silicon nitride oxide is a material that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, “substantially parallel” indicates a state where two straight lines are placed at an angle greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be called a transistor including a metal oxide or an oxide semiconductor.

In this specification and the like, normally off means drain current per micrometer of channel width flowing through a transistor being 1×10⁻²⁰ A or less at room temperature, 1×10⁻¹⁸ A or less at 85° C., or 1×10⁻¹⁶ A or less at 125° C. when a potential is not applied to a gate or a ground potential is applied to the gate.

### Embodiment 1

An example of a semiconductor device including a transistor of one embodiment of the present invention is described in this embodiment. The semiconductor device including a transistor of one embodiment of the present invention is a transistor including an oxide semiconductor in its channel formation region.

### <Structure Example of Semiconductor Device>

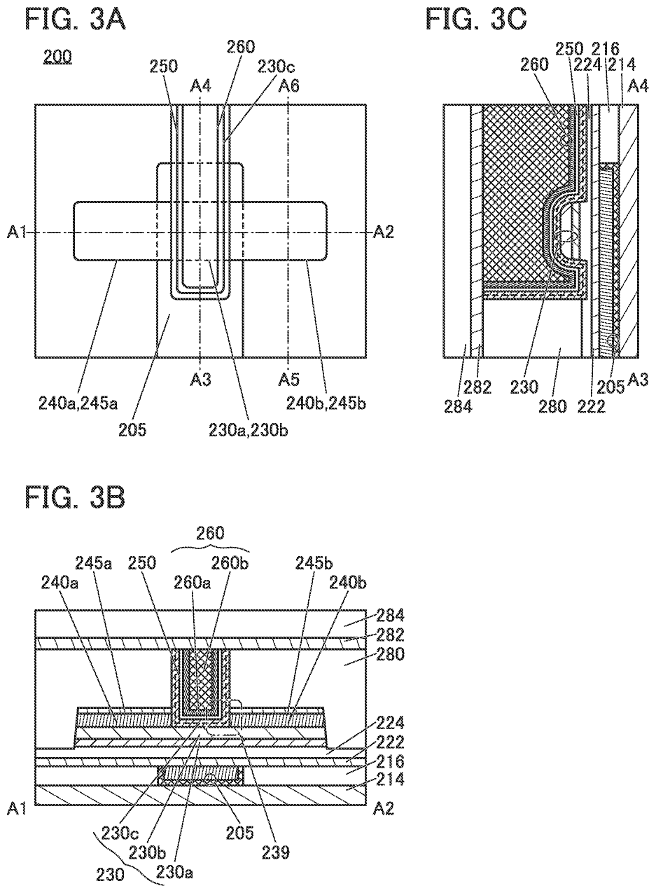

FIG. 3 show a top view and cross-sectional views of a semiconductor device including the transistor 200 of one embodiment of the present invention. FIG. 3A is a top view of the semiconductor device. FIG. 3B and FIG. 3C are cross-sectional views of the semiconductor device. Here, FIG. 3B is a cross-sectional view of a portion indicated by the dashed-dotted line A1-A2 in FIG. 3A. FIG. 3C is a cross-sectional view of a portion indicated by the dashed-dotted line A3-A4 in FIG. 3A. Note that for clarity of the drawing, some components are not illustrated in the top view of FIG. 3A.

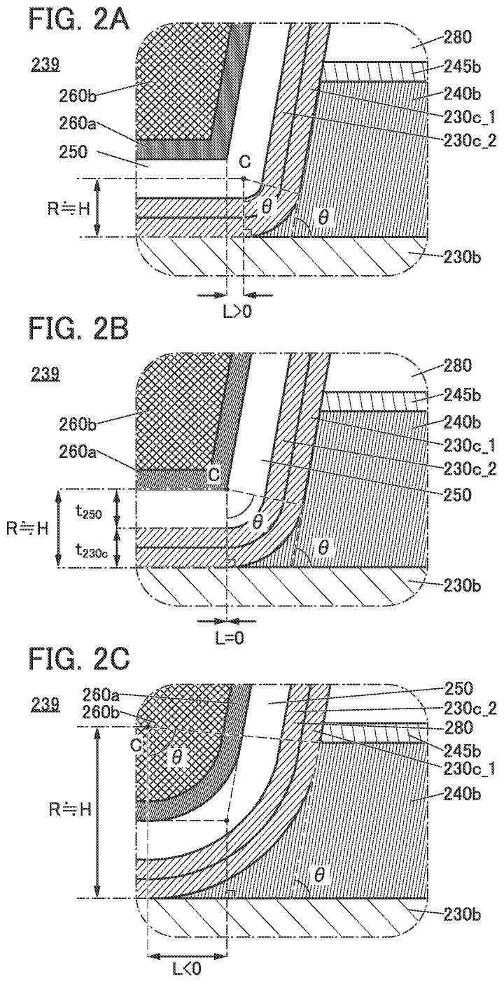

FIG. 2 shows enlarged views of a region 239 enclosed by the dashed-dotted line illustrated in FIG. 3B.

The semiconductor device of one embodiment of the present invention includes the transistor 200, and an insulator 214, an insulator 216, an insulator 280, an insulator 282, and an insulator 284 that function as interlayer films. Note that the insulator 280 is provided to be in contact with at least an oxide 230.

### [Transistor 200]

As illustrated in FIG. 3, the transistor 200 is positioned over a substrate (not illustrated) and includes a conductor 205 that is positioned to be embedded in the insulator 216, an insulator 222 positioned over the insulator 216 and the conductor 205, an insulator 224 positioned over the insulator 222, the oxide 230 (an oxide 230a, an oxide 230b, an oxide 230c) positioned over the insulator 224, an insulator 250 positioned over the oxide 230, a conductor 260 (a conductor 260a and a conductor 260b) positioned over the insulator 250, a conductor 240a and a conductor 240b in contact with part of the top surface of the oxide 230b, an insulator 245a over the conductor 240a, and an insulator 245b over the conductor 240b.

Note that the conductor 260 and the conductor 205 function as gate electrodes. The conductor 240a and the conductor 240b function as a source electrode and a drain electrode. The oxide 230b is an oxide semiconductor and includes a region where a channel is formed. The insulator 222, the insulator 224, and the insulator 250 function as gate insulators.

Thus, a metal oxide functioning as an oxide semiconductor (hereinafter, also referred to as an oxide semiconductor) is preferably used for the oxide 230b including the channel formation region.

The transistor 200 including an oxide semiconductor in the channel formation region has an extremely low leakage current in a non-conduction state; hence, a low-power semiconductor device can be provided. An oxide semiconductor can be deposited by a sputtering method or the like. This allows the transistor 200 to be stacked over another structure body, leading to the construction of a highly integrated semiconductor device.

Note that the oxide semiconductor functioning as the channel formation region has a band gap of preferably 2 eV or higher, further preferably 2.5 eV or higher. With the use of an oxide semiconductor having such a wide band gap, the off-state current of the transistor can be reduced.

An oxide semiconductor can be used for the oxide 230c in a manner similar to that of the oxide 230b. Therefore, the channel formation region is formed also in the oxide 230c in some cases. A metal oxide having a wider bandgap than the oxide 230b may be used for the oxide 230c. Thus, the oxide 230c functions as the gate insulator in some cases.

The oxide 230c may have a stacked-layer structure of two or more layers, as illustrated in FIG. 2. For example, the oxide 230c includes a first oxide (an oxide 230c_1) of the oxide 230c and a second oxide (an oxide 230c_2) of the oxide 230c placed over the first oxide of the oxide 230c in FIG. 2.

In the transistor 200 illustrated in FIG. 3, at least the oxide 230c, the insulator 250, and the conductor 260 are provided in an opening portion included in the insulator 280. Thus, at least the oxide 230a and the oxide 230b are exposed on a bottom surface of the opening portion. At least side surfaces of the conductor 240a and the conductor 240b are exposed on a side surface of the opening portion.

In other words, the width of the opening portion included in the insulator 280 is the distance that contributes to determination of the channel length of the transistor 200, and therefore the width of the opening portion (corresponding to the shortest distance between the conductor 240a and the conductor 240b in FIG. 3) is preferably set to the minimum feature size.

In the present invention, the oxide 230c preferably has a function of inhibiting diffusion of oxygen (hereinafter also referred to as a barrier property) as compared to the insulator 250. When the oxide 230c has a barrier property against oxygen, it is possible to inhibit oxidation of an end portion of the conductor 240 due to oxygen diffusing from a structure body above the oxide 230c or it is possible to inhibit oxidation of an end portion of the conductor 240 accompanying treatment in the post-process.

In a minute transistor, when an end portion of the conductor 240 is oxidized, a high-resistance region is formed between the channel formation region and the source electrode or the drain electrode. Consequently, the on-state current of the transistor 200 and frequency characteristics are possibly reduced. Moreover, there is a high probability that the high-resistance region causes a variation in channel length among the transistors 200.

As the opening portion provided in the insulator 280 is miniaturized, deposition and processing of the structure body provided in the opening portion become more difficult. In the opening portion, a defect such as a void may be generated at a corner portion formed by the bottom surface and the side surface, for example. Particularly when a stacked-layer structure of thin films is provided, there is a high probability that coverage with the upper layer is poor and a defect is generated in a film formed inside the opening portion.

Note that in this specification, a function of inhibiting diffusion of impurities or oxygen means a function of inhibiting diffusion of any one or all of the impurities and the oxygen. In addition, a film having a function of inhibiting diffusion of hydrogen or oxygen may be referred to as a film through which hydrogen or oxygen does not pass easily, a film having low permeability of hydrogen or oxygen, a film having a barrier property against hydrogen or oxygen, or a barrier film against hydrogen or oxygen, for example. A barrier film having conductivity is sometimes referred to as a conductive barrier film.

The oxide 230b exposed on the bottom surface of the opening portion included in the insulator 280 becomes the channel formation region. Thus, when a defect is generated in the oxide 230c and the insulator 250, the insulator 250 functioning as a gate insulating film over the channel formation region may become uneven to cause a variation in electrical characteristics among the transistors or to reduce reliability. Furthermore, there is a possibility that electrical continuity is established between the conductor 260 functioning as the gate electrode and the oxide 230b functioning as a semiconductor and an insulation state fails to be maintained.

In view of the above, the shape of the side surface of the conductor 240, which is exposed in the opening portion included in the insulator 280, is optimized so as to gradually change the inclination of a deposition surface when a film to be the oxide 230c or a film to be the insulator 250 is deposited, thereby inhibiting generation of a defect in the film to be the oxide 230c or the film to be the insulator 250. That is, the shape of the side surface of the conductor 240b is optimized so that the coverage with the film provided in the opening portion can be favorable.

When the oxide 230c is uniformly formed on the side surface of the conductor 240, oxidation of the side surface of the conductor 240 can be prevented. The gate insulator over the channel formation region can be uniformly deposited. Consequently, when a plurality of transistors 200 are provided, a semiconductor device with a small variation among the transistors can be provided. A highly reliable semiconductor device can be provided.

Specifically, a lower end portion of the side surface of the conductor 240 exposed in the opening portion included in the insulator 280 has a curved shape. For example, a side surface of the lower end portion of the conductor 240 preferably touches a circle or an ellipse having a center above the oxide 230b.

Note that the center of an ellipse is the intersection point of the short axis and the long axis of the ellipse. The center of a circle is the intersection point of at least three or more lines perpendicular to the tangent lines to the circle, which are drawn at varied positions of the circle.

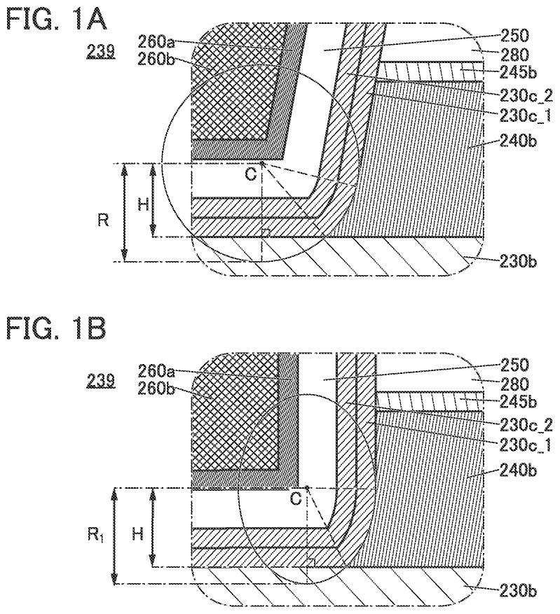

For example, the case where a lower end portion of the side surface of the conductor 240b touches a circle having a center above the oxide 230b is described using FIG. 1A and FIG. 2A to FIG. 2C. Note that FIG. 1A and FIG. 2A to FIG. 2C are enlarged views of the region 239 enclosed by the dashed-dotted line in FIG. 3B.

On the side surface of the conductor 240b exposed in the opening portion included in the insulator 280, the lower end portion of the conductor 240b touches a circle having a center C above the oxide 230b and a radius R, as illustrated in FIG. 1A. That is, the lower end portion of the conductor 240b has a curve like an arc with a radius R of curvature.

In the above structure, the length H of the perpendicular line to the top surface of the oxide 230b from the center C of the above circle is preferably shorter than or equal to the radius R. That is, preferably, the radius R of the circle≥the length H of the perpendicular line. Note that when the radius R of the circle<the length H of the perpendicular line, there is a high probability that an inflection point is formed at the lower end portion of the conductor 240b and coverage with a film formed above the conductor 240b is made poor.

Here, the cases where the radius R of the circle is a value approximate to the length H of the perpendicular line to the oxide 230b from the center C of the circle (the radius R of the circle the length H of the perpendicular line) are described using FIG. 2A to FIG. 2C.

For example, in FIG. 2A to FIG. 2C, the lower end portion of the conductor 240b preferably has the curvature center C above the oxide 230b and a curve like an arc with the radius R of curvature. The radius R of the circle is almost equal to the length H of the perpendicular line to the oxide 230b from the curvature center C.

In FIG. 2A to FIG. 2C, an angle θ of a dihedral angle between a tangent plane touching the above curve like an arc at a termination portion of the curve and the top surface of the oxide 230b (also referred to as an angle θ of a taper angle) is as follows: 0°<θ≤90°. That is, the range is set such that the side surface of the conductor 240b does not have an undercut shape.

Since the lower end portion of the side surface of the conductor 240b exposed in the opening portion included in the insulator 280 has a curved shape, coverage with a film formed over the channel formation region included in the oxide 230b can be improved.

As illustrated in FIG. 2A and FIG. 2B, an upper end portion of the side surface of the conductor 240b exposed in the opening portion included in the insulator 280 may be a flat surface. Note that the angle of a dihedral angle between an extended surface of the flat surface and the top surface of the oxide 230b is greater than or equal to 0° and less than or equal to the angle θ of the taper angle. That is, the range is set such that the side surface of the conductor 240b does not have an undercut shape.

Note that as illustrated in FIG. 2, when the dihedral angle between the extended surface of the flat surface of the side surface of the conductor 240b and the top surface of the oxide 230b is equal to the angle θ of the taper angle, the upper end portion of the side surface of the conductor 240b overlaps with the tangent line touching the above curve like an arc at a termination portion of the curve in a cross-sectional view in the channel length direction. In other words, when the dihedral angle between the tangent plane including the flat surface of the upper end portion of the side surface of the conductor 240b, which touches the termination portion of the curve, and the top surface of the oxide 230b is preferably 0, in which case the oxide 230c and the insulator 250, in particular, can be not only deposited over the channel formation region but also be deposited uniformly.

As illustrated in FIG. 2B, when the curvature radius R is greater than or equal to the total thickness of the oxide 230c and the insulator 250 (when R≥t_{230c}+t₂₅₀, where t_{230c} is the thickness of the oxide 230c and t₂₅₀ is the thickness of the insulator 250), a horizontal distance L between a side formed by a bottom surface of the conductor 260 and a side surface of the conductor 260 and a lower end portion of the conductor 240b is less than or equal to 0. Note that when the horizontal distance L is less than 0, i.e., negative, there is a region where the bottom surface of the conductor 260 and the termination portion of the conductor 240b overlap with each other.

Note that a film thickness (t) means the length of a perpendicular line from the top surface of an insulating film to the bottom surface of the insulating film.

Thus, when R≥t_{230c}+t₂₅₀, a high-resistance region is not formed between the channel formation region generated in the oxide 230b and the source region or the drain region, so that the on-state current of the transistor 200 can be increased and frequency characteristics can be improved.

Note that as illustrated in FIG. 2C, when the bonding surface between the bottom surface of the conductor 260 and the side surface of the conductor 260 is curved, the horizontal distance L between a side, where the extended surface of the bottom surface of the conductor 260 and the extended surface of the side surface of the conductor 260 intersect with each other, and the lower end portion of the conductor 240b is preferably less than or equal to 0.

The cases where the curvature radius R is a value approximate to the length H of the line perpendicular to the oxide 230b from the curvature center C (the radius R of the circle the length H of the perpendicular line) are described above. Then, the case where the lower end portion of the side surface of the conductor 240b touches an ellipse having a center above the oxide 230b is described using FIG. 1B.

On the side surface of the conductor 240b exposed in the opening portion included in the insulator 280, the lower end portion of the conductor 240b touches an ellipse having a center C above the oxide 230b and a semi-major axis R₁, as illustrated in FIG. 1B. That is, the lower end portion of the conductor 240b has a curve like an ellipse.

Preferably, an inflection point is not formed in the lower end portion of the conductor 240b in the above structure. Preferably, a so-called undercut shape is not formed in the side surface of the conductor 240b. Thus, the length H of the perpendicular line to the top surface of the oxide 230b from the center C of the above ellipse is preferably at least shorter than or equal to the radius R₁. That is, preferably, the semi-major axis R₁ of the ellipse the length H of the perpendicular line.

As described above, the case where the lower end portion of the side surface of the conductor 240b touches an ellipse having a center above the oxide 230b is described.

In view of the above, the shape of the side surface of the conductor 240, which is exposed in the opening portion included in the insulator 280, is optimized so as to gradually change the inclination of a deposition surface when a film to be the oxide 230c or a film to be the insulator 250 is deposited, thereby inhibiting generation of a defect in the film to be the oxide 230c or the film to be the insulator 250.

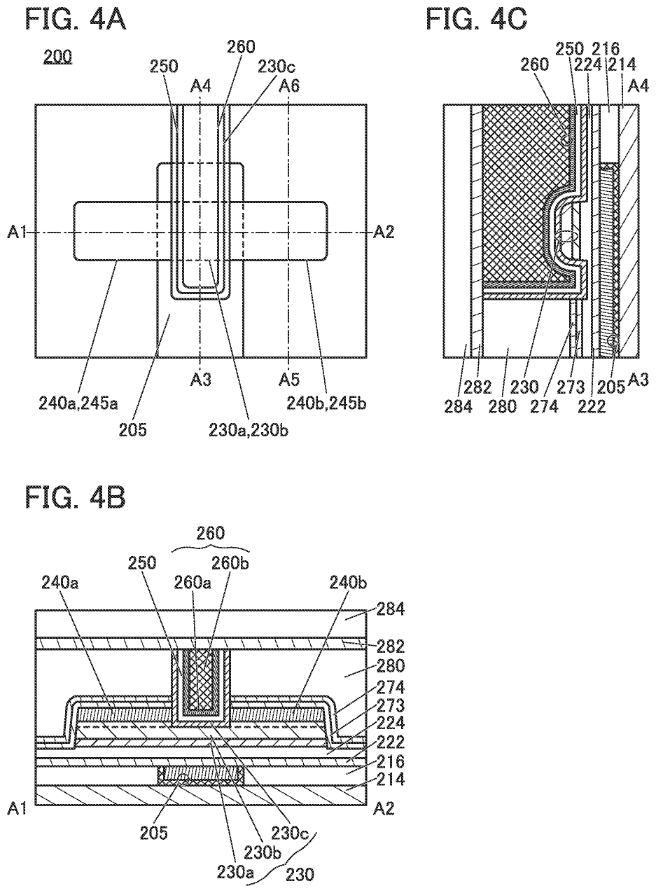

Detailed structures of the transistor 200 will be described below with reference to FIG. 3 and FIG. 4.

In the transistor 200, a metal oxide functioning as an oxide semiconductor (hereinafter, also referred to as an oxide semiconductor) is preferably used for the oxide 230 (mainly for the oxide 230b) including the region where the channel is formed.

The transistor 200 including an oxide semiconductor in the channel formation region has an extremely low leakage current in a non-conduction state; hence, a low-power semiconductor device can be provided. An oxide semiconductor can be deposited by a sputtering method or the like. This allows the transistor 200 to be stacked over another structure body, leading to the construction of a highly integrated semiconductor device.

Note that the oxide semiconductor functioning as the channel formation region has a band gap of preferably 2 eV or higher, further preferably 2.5 eV or higher. With the use of an oxide semiconductor having such a wide band gap, the off-state current of the transistor can be reduced.

Specifically, for example, a metal oxide such as an In-M-Zn oxide (an element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used as the oxide semiconductor. As the oxide semiconductor, an In—Ga oxide or an In—Zn oxide may be used.

Note that in some cases, a transistor using an oxide semiconductor has normally-on characteristics (characteristics in that a channel exists without voltage application to a gate electrode and current flows in a transistor) owing to an impurity and an oxygen vacancy in the oxide semiconductor that affect the electrical characteristics. In the case where the transistor is driven in the state where excess oxygen exceeding the proper amount is included in the oxide semiconductor, the valence of the excess oxygen atoms is changed and the electrical characteristics of the transistor are changed, so that reliability is decreased in some cases.

Therefore, it is preferable to use, as the oxide semiconductor used in the transistor, a highly purified intrinsic oxide semiconductor that does not include an impurity, an oxygen vacancy, and oxygen in excess of oxygen in the stoichiometric composition (hereinafter, also referred to as excess oxygen).

The oxide 230 preferably has a stacked-layer structure of a plurality of oxide layers with different chemical compositions. Specifically, the atomic ratio of the element M to In in the metal oxide used as the oxide 230a is preferably higher than the atomic ratio of the element M to In in the metal oxide used as the oxide 230b.

A metal oxide that can be used as the oxide 230a or the oxide 230b can be used as the oxide 230c.

For example, an In—Ga—Zn oxide, a Ga—Zn oxide, gallium oxide, or the like may be used for the oxide 230a and the oxide 230c in the case where the oxide 230b is an In—Ga—Zn oxide.

The oxide 230b and the oxide 230c preferably have crystallinity. For example, a CAAC-OS (c-axis aligned crystalline oxide semiconductor) described later is preferably used. An oxide having crystallinity, such as a CAAC-OS, has a dense structure with small amounts of impurities and defects (e.g., oxygen vacancies) and high crystallinity. This can inhibit oxygen extraction from the oxide 230b by the source electrode or the drain electrode. This can reduce oxygen extraction from the oxide 230b even when heat treatment is performed; thus, the transistor 200 is stable with respect to high temperatures in a manufacturing process (what is called thermal budget).

Although a structure in which the oxide 230 has a three-layer stacked structure of the oxide 230a, the oxide 230b, and the oxide 230c in the transistor 200 is described, the present invention is not limited thereto. For example, the oxide 230 may be a single layer of the oxide 230b or has a two-layer structure of the oxide 230a and the oxide 230b, a two-layer structure of the oxide 230b and the oxide 230c, or a stacked-layer structure including four or more layers. Alternatively, each of the oxide 230a, the oxide 230b, and the oxide 230c may have a stacked-layer structure.

For example, in FIG. 1, the first oxide (oxide 230c_1) of the oxide 230c and the second oxide (oxide 230c_2) of the oxide 230c over the first oxide of the oxide 230c are included.

For example, the oxide 230c_1 preferably includes at least one of the metal elements included in the metal oxide used as the oxide 230b, and further preferably includes all of these metal elements. For example, an In—Ga—Zn oxide is used as the oxide 230c_1, and an In—Ga—Zn oxide, a Ga—Zn oxide, or gallium oxide is used as the oxide 230c_2. Owing to the structure, the density of defect states at the interface between the oxide 230b and the oxide 230c_1 can be decreased.

The oxide 230c_2 is preferably a metal oxide that inhibits diffusion or passage of oxygen, compared to the oxide 230c_1. Providing the oxide 230c_2 between the insulator 250 and the oxide 230c_1 can inhibit diffusion of oxygen included in the insulator 280 into the insulator 250. Accordingly, the oxygen is more likely to be supplied to the oxide 230b through the oxide 230c_1.

When the atomic ratio of In to the metal element of the main component in the metal oxide used as the oxide 230c2 is lower than the atomic ratio of In to the metal element of the main component in the metal oxide used as the oxide 230c_1, the diffusion of In into the insulator 250 side can be inhibited. Since the insulator 250 functions as a gate insulator, the transistor exhibits poor characteristics when In enters the insulator 250 and the like. Thus, when the oxide 230c has a stacked-layer structure, a highly reliable semiconductor device can be provided.

The conductor 260 functions as a first gate (also referred to as a top gate) electrode.

Here, the conductor 260 is embedded in an opening in the insulator 280 and the like to form the transistor 200. In the step of forming the opening, part of a conductive layer to be the conductor 240 is exposed on the bottom of the opening in the insulator 280. In the conductive layer to be the conductor 240, a region overlapping with the bottom of the opening provided in the insulator 280 is removed, so that the conductor 240a and the conductor 240b are formed.

Thus, an end portion of the conductor 240a and an end portion of the conductor 240b are on the same plane as the side surfaces of the opening. The conductor 260 is embedded in the opening formed in the insulator 280 with the insulator 250 and the like therebetween, whereby the conductor 260 can be arranged in a self-aligned manner without alignment in a region between the conductor 240a and the conductor 240b.

Moreover, as shown in FIG. 3B or FIG. 3C, the top surface of the conductor 260 is substantially aligned with the top surface of the insulator 250 and the top surface of the oxide 230c.

In a region where the conductor 260 does not overlap with the oxide 230, the shortest distance between the surface where the conductor 260 is in contact with the insulator 250 and the top surface of the insulator 222 is preferably shorter than the shortest distance between the surface where the oxide 230b is in contact with the oxide 230a and the top surface of the insulator 222, as shown in FIG. 3C. That is, in the channel width direction of the transistor 200, a side surface of the oxide 230b is covered by the conductor 260 with at least the insulator 250 therebetween.

When the conductor 260 functioning as the gate electrode covers the side and top surfaces of the channel formation region of the oxide 230b with the insulator 250 and the like therebetween, the electric field of the conductor 260 is likely to affect the entire channel formation region of the oxide 230b. Thus, the on-state current of the transistor 200 can be increased and the frequency characteristics of the transistor 200 can be improved.

Note that the conductor 260 preferably includes the conductor 260a and the conductor 260b positioned over the conductor 260a. For example, the conductor 260a is preferably positioned to cover a bottom surface and a side surface of the conductor 260b.

For the conductor 260a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of oxygen atoms, oxygen molecules, and the like).

In addition, when the conductor 260a has a function of inhibiting diffusion of oxygen, the conductivity of the conductor 260b can be inhibited from being lowered because of oxidation due to oxygen contained in the insulator 250. As a conductive material having a function of inhibiting diffusion of oxygen, for example, tantalum, tantalum nitride, ruthenium, or ruthenium oxide is preferably used.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure, for example, a stacked-layer structure of any of the above conductive materials and titanium or titanium nitride.

Although the conductor 260 has a two-layer structure of the conductor 260a and the conductor 260b in FIG. 3, the conductor 260 may have a single-layer structure or a stacked-layer structure of three or more layers.

The conductor 205 sometimes functions as a second gate (also referred to as bottom gate) electrode.

When the conductor 205 functions as a gate electrode, by changing a potential applied to the conductor 205 not in conjunction with but independently of a potential applied to the conductor 260, the threshold voltage (Vth) of the transistor 200 can be adjusted. In particular, by applying a negative potential to the conductor 205, Vth of the transistor 200 can be further increased, and the off-state current can be reduced. Thus, drain current when a potential applied to the conductor 260 is 0 V can be lower in the case where a negative potential is applied to the conductor 205 than in the case where the negative potential is not applied to the conductor 205.

The conductor 205 is provided to overlap with the oxide 230 and the conductor 260. Furthermore, the conductor 205 is preferably provided to be embedded in the insulator 214 or the insulator 216.

Note that in the channel width direction, the conductor 205 is preferably provided larger than the channel formation region of the oxide 230. As shown in FIG. 3C, it is particularly preferable that the conductor 205 extend to a region outside an end portion of the oxide 230 that intersects with the channel width direction.

That is, the conductor 205 and the conductor 260 preferably overlap with each other with the insulators therebetween on an outer side of the side surface of the oxide 230 in the channel width direction. Since the above-described structure is included, the channel formation region of the oxide 230 can be electrically surrounded by the electric field of the conductor 260 functioning as the first gate electrode and the electric field of the conductor 205 functioning as the second gate electrode.

In FIG. 3, the conductor 205 has a structure in which a first conductor and a second conductor are stacked, and the present invention is not limited thereto. For example, the conductor 205 may have a single-layer structure or a stacked-layer structure of three or more layers. In the case where a structure body has a stacked-layer structure, layers may be distinguished by ordinal numbers corresponding to the formation order.

Here, for the first conductor of the conductor 205, a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom is preferably used. Alternatively, it is preferable to use a conductive material having a function of inhibiting diffusion of oxygen (e.g., at least one of oxygen atoms, oxygen molecules, and the like).

When a conductive material having a function of inhibiting diffusion of oxygen is used for the first conductor of the conductor 205, a reduction in the conductivity of the second conductor of the conductor 205 due to oxidation can be inhibited. As a conductive material having a function of inhibiting diffusion of oxygen, for example, tantalum, tantalum nitride, ruthenium, or ruthenium oxide is preferably used. Accordingly, the first conductor of the conductor 205 is a single layer or stacked layers of the above conductive materials. For example, the first conductor of the conductor 205 may be a stack of tantalum, tantalum nitride, ruthenium, or ruthenium oxide and titanium or titanium nitride.

A conductive material containing tungsten, copper, or aluminum as its main component is preferably used for the second conductor of the conductor 205. Note that the second conductor of the conductor 205 is a single layer in the drawing but may have a stacked-layer structure, for example, a stacked-layer structure of the above conductive material and titanium or titanium nitride.

Furthermore, as shown in FIG. 3C, the conductor 205 extends to function as a wiring as well. However, without limitation to this structure, a structure where a conductor functioning as a wiring is provided below the conductor 205 may be employed. In addition, the conductor 205 does not necessarily have to be provided in each transistor. For example, the conductor 205 may be shared by a plurality of transistors.

The conductor 240 (the conductor 240a and the conductor 240b) functions as a source electrode or a drain electrode.

As the conductor 240, TaNₓO_{y} is preferably used, for example. Note that TaNₓO_{y} may contain aluminum. As another example, titanium nitride, a nitride containing titanium and aluminum, ruthenium oxide, an oxide containing strontium and ruthenium, or an oxide containing lanthanum and nickel may be used. These materials are preferable because they are conductive materials that are not easily oxidized or materials that maintain the conductivity even when absorbing oxygen.

Over the conductor 240, an insulator 245 functioning as a barrier layer is preferably provided.

The insulator 245 is preferably in contact with the top surface of the conductor 240 as shown in FIG. 3B. The structure can inhibit absorption of excess oxygen in the insulator 280 by the conductor 240. Furthermore, by inhibiting oxidation of the conductor 240, an increase in the contact resistance between the transistor 200 and a wiring can be inhibited. Consequently, the transistor 200 can have favorable electrical characteristics and reliability.

The insulator 245 preferably has a function of inhibiting diffusion of oxygen. For example, the insulator 245 preferably has a function of inhibiting oxygen diffusion more than the insulator 280.

An insulator containing an oxide of one or both of aluminum and hafnium is preferably deposited as the insulator 245, for example. An insulator containing aluminum nitride may be used as the insulator 245, for example.

The insulator 250 functions as the first gate insulator.

The insulator 250 is preferably positioned in contact with the oxide 230c. For the insulator 250, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used. In particular, silicon oxide and silicon oxynitride, which have thermal stability, are preferable.

Note that microwave-excited plasma treatment may be performed under an atmosphere containing oxygen after the insulator 250 is deposited. By performing microwave-excited plasma treatment, an impurity in the insulator 250, such as hydrogen, water, or an impurity can be removed. Furthermore, microwave-excited plasma treatment improves the film quality of the insulator 250, whereby diffusion of hydrogen, water, an impurity, or the like can be inhibited. Accordingly, hydrogen, water, or an impurity can be inhibited from being diffused into the oxide 230 through the insulator 250 in the following step such as deposition of a conductive film to be the conductor 260 or the following treatment such as heat treatment.

In solid silicon oxide, for example, bond energy between a hydrogen atom and a silicon atom is 3.3 eV, bond energy between a carbon atom and a silicon atom is 3.4 eV, and bond energy between a nitrogen atom and a silicon atom is 3.5 eV. Thus, in order to remove a hydrogen atom bonded to a silicon atom, radicals or ions having an energy of at least greater than or equal to 3.3 eV are made to collide with a bond portion between the hydrogen atom and the silicon atom to cut the bond between the hydrogen atom and the silicon atom.

Note that the same applies to other impurities such as nitrogen and carbon; radicals or ions having energy at least greater than or equal to bond energy are made to collide with a bond portion between an impurity atom and a silicon atom to cut the bond between the impurity atom and the silicon atom.

Here, examples of radicals and ions generated by microwave-excited plasma include O(³P), which is an oxygen atom radical in the ground state, O(¹D), which is an oxygen atom radical in the first excited state, and O₂+, which is a monovalent cation of an oxygen molecule. The energy of O(³P) is 2.42 eV, and the energy of O(¹D) is 4.6 eV. Furthermore, the energy of O₂⁺ having charges is not uniquely determined because it is accelerated by the potential distribution in plasma and a bias; however, at least only the internal energy is higher than the energy of O(¹D).

That is, radicals and ions such as O(¹D) and O₂⁺ can cut the bond between each of hydrogen, nitrogen, and a carbon atom in the insulator 250 and a silicon atom to remove hydrogen, nitrogen, and carbon bonded to the silicon atom. Furthermore, the impurities such as hydrogen, nitrogen, and carbon can also be reduced by thermal energy and the like applied to a substrate in performing the microwave-excited plasma treatment.

On the other hand, O(³P) has low reactivity, and thus does not react in the insulator 250 and is diffused deeply in the film. Alternatively, O(³P) reaches the oxide 230 through the insulator 250, and is diffused into the oxide 230. When O(³P) diffused into the oxide 230 comes close to the oxygen vacancy hydrogen enters, hydrogen in the oxygen vacancy is released from the oxygen vacancy and O(³P) enters the oxygen vacancy instead; thus, the oxygen vacancy is filled. Accordingly, an electron serving as a carrier can be inhibited from being generated in the oxide 230.

The proportion of O(³P) in the total radicals and ion species increases when microwave-excited plasma treatment is performed under a high pressure condition. The proportion of O(³P) is preferably high for compensation of the oxygen vacancies in the oxide 230. Thus, the pressure during the microwave-excited plasma treatment is higher than or equal to 133 Pa, preferably higher than or equal to 200 Pa, further preferably higher than or equal to 400 Pa. Furthermore, the oxygen flow rate ratio (O₂/O₂₊Ar) is lower than or equal to 50%, preferably higher than or equal to 10% and lower than or equal to 30%.

For the insulator 250, an oxide material that releases part of oxygen by heating is preferably used. An oxide that releases oxygen by heating is an oxide film in which the amount of released oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in TDS (Thermal Desorption Spectroscopy) analysis. Note that the temperature of the film surface in the TDS analysis is preferably within the range of 100° C. to 700° C., or 100° C. to 400° C.

When an insulator that releases oxygen by heating is provided as the insulator 250 in contact with the top surface of the oxide 230c, oxygen can be efficiently supplied to the channel formation region of the oxide 230b and oxygen vacancies in the channel formation region of the oxide 230b can be reduced. Thus, a transistor that has stable electrical characteristics with a small variation in electrical characteristics and improved reliability can be provided. Furthermore, the concentration of impurities such as water and hydrogen in the insulator 250 is preferably reduced.

Furthermore, a metal oxide may be provided between the insulator 250 and the conductor 260. The metal oxide preferably inhibits diffusion of oxygen from the insulator 250 into the conductor 260. Providing the metal oxide that inhibits diffusion of oxygen inhibits diffusion of oxygen from the insulator 250 into the conductor 260. That is, a reduction in the amount of oxygen supplied to the oxide 230 can be inhibited. In addition, oxidation of the conductor 260 due to oxygen from the insulator 250 can be inhibited.

Note that the metal oxide functions as part of the gate insulator in some cases. Therefore, when silicon oxide, silicon oxynitride, or the like is used for the insulator 250, a metal oxide that is a high-k material with a high dielectric constant is preferably used as the metal oxide. When the gate insulator has a stacked-layer structure of the insulator 250 and the metal oxide, the stacked-layer structure can be thermally stable and have a high dielectric constant. Thus, a gate potential that is applied during operation of the transistor can be reduced while the physical thickness of the gate insulator is maintained. Furthermore, the equivalent oxide thickness (EOT) of the insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. In particular, an insulator containing an oxide of one or both of aluminum and hafnium is preferably used.

The metal oxide may have a function of part of the first gate electrode. For example, an oxide semiconductor that can be used for the oxide 230 can be used as the metal oxide. In that case, when the conductor 260 is deposited by a sputtering method, the metal oxide can have a reduced electric resistance value to be a conductor.

With the metal oxide, the on-state current of the transistor 200 can be increased without a reduction in the influence of the electric field from the conductor 260. Since the distance between the conductor 260 and the oxide 230 is kept by the physical thicknesses of the insulator 250 and the metal oxide, leakage current between the conductor 260 and the oxide 230 can be reduced. Moreover, when the stacked-layer structure of the insulator 250 and the metal oxide is provided, the physical distance between the conductor 260 and the oxide 230 and the intensity of electric field applied to the oxide 230 from the conductor 260 can be easily adjusted as appropriate.

The insulator 222 and the insulator 224 function as a second gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of further inhibiting diffusion of one or both of hydrogen and oxygen as compared to the insulator 224.

For the insulator 222, an insulator containing an oxide of one or both of aluminum and hafnium, which is an insulating material, is preferably used. In particular, it is preferable that aluminum oxide, hafnium oxide, an oxide containing aluminum and hafnium (hafnium aluminate), or the like be used as the insulator. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen inside the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over these insulators may be used as the insulator 222.

A single layer or stacked layers of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) may be used as the insulator 222. With miniaturization and high integration of transistors, a problem such as leakage current may arise because of a thinner gate insulator. When a high-k material is used as an insulator functioning as the gate insulator, a gate potential during operation of the transistor can be lowered while the physical thickness of the gate insulator is maintained.

It is preferable that oxygen be released from the insulator 224 in contact with the oxide 230 by heating like the insulator 250. Silicon oxide, silicon oxynitride, or the like is used as appropriate for the insulator 224, for example. When an insulator containing oxygen is provided in contact with the oxide 230, oxygen vacancies in the oxide 230 can be reduced and the reliability of the transistor 200 can be improved.

Note that the insulator 222 and the insulator 224 may each have a stacked-layer structure of two or more layers. In such cases, without limitation to a stacked-layer structure formed of the same material, a stacked-layer structure formed of different materials may be employed.

The insulator 214, the insulator 216, the insulator 280, the insulator 282, and the insulator 284 function as interlayer films.

The insulator 214 preferably functions as an insulating barrier film that inhibits diffusion of impurities such as water and hydrogen from the substrate side into the transistor 200. Accordingly, for the insulator 214, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use an insulating material having a function of inhibiting diffusion of oxygen (e.g., at least one of an oxygen atom, an oxygen molecule, and the like).

For example, aluminum oxide, silicon nitride, or the like is preferably used for the insulator 214. Accordingly, impurities such as water and hydrogen can be inhibited from being diffused into the transistor 200 side from the substrate side through the insulator 214. Alternatively, oxygen contained in the insulator 224 and the like can be inhibited from being diffused into the substrate side through the insulator 214. Note that the insulator 214 may have a stacked-layer structure of two or more layers. In such cases, without limitation to a stacked-layer structure formed of the same material, a stacked-layer structure formed of different materials may be employed. For example, a stack of aluminum oxide and silicon nitride may be employed.

Furthermore, the insulator 214 is preferably formed of silicon nitride by a sputtering method, for example. In this manner, the hydrogen concentration in the insulator 214 can be reduced, and impurities such as water and hydrogen can be further inhibited from being diffused into the transistor 200 side from the substrate side through the insulator 214.

The permittivity of the insulator 216 functioning as an interlayer film is preferably lower than the permittivity of the insulator 214. When a material with a low permittivity is used for an interlayer film, the parasitic capacitance generated between wirings can be reduced. For the insulator 216, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate, for example.

The insulator 216 preferably includes a region that has a low hydrogen concentration and contains oxygen in excess of that in the stoichiometric composition (hereinafter also referred to as an excess-oxygen region), or preferably contains oxygen that is released by heating (hereinafter also referred to as excess oxygen).

As the insulator including an excess-oxygen region, specifically, an oxide material that releases part of oxygen by heating is preferably used. An oxide that releases oxygen by heating (hereinafter also referred to as an insulating material including an excess-oxygen region) is an oxide film in which the amount of released oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in TDS (Thermal Desorption Spectroscopy) analysis. Note that the temperature of the film surface in the TDS analysis is preferably within the range of 100° C. to 700° C., or 100° C. to 400° C.

Specifically, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like containing excess oxygen can be used. In particular, silicon oxide and silicon oxynitride, which have thermal stability, are preferable.

For example, silicon oxide deposited by a sputtering method is preferably used for the insulator 216. Thus, entry of hydrogen into the oxide 230 can be inhibited; alternatively, oxygen can be supplied to the oxide 230 to reduce oxygen vacancies in the oxide 230. Thus, a transistor that has stable electrical characteristics with a small variation in electrical characteristics and improved reliability can be provided.

Note that the insulator 216 may have a stacked-layer structure. For example, in the insulator 216, an insulator similar to the insulator 214 may be provided at least in a portion in contact with a side surface of the conductor 205. With such a structure, oxidization of the conductor 205 due to oxygen contained in the insulator 216 can be inhibited. Alternatively, a reduction in the amount of oxygen contained in the insulator 216 due to the conductor 205 can be inhibited.

The insulator 280 is provided over the insulator 224, the oxide 230, and the conductor 240. In addition, a top surface of the insulator 280 may be planarized.

Note that, in the transistor using the oxide semiconductor, oxygen in the oxide semiconductor is gradually absorbed by a conductor included in the transistor or a conductor used for a plug or a wiring connected to the transistor, and an oxygen vacancy is generated as one of changes over time in some cases.

Accordingly, it is preferable to provide a structure body including an excess-oxygen region in the vicinity of the oxide semiconductor of the transistor. Excess oxygen of the structure body including the excess-oxygen region is diffused into oxygen vacancies generated in the oxide semiconductor, whereby the oxygen vacancies can be compensated for.

Specifically, an insulator containing oxygen is used as the insulator 280 functioning as an interlayer film in the vicinity of the transistor 200. It is particularly preferable to use, for the insulator 280, an oxide that contains more oxygen than oxygen in the stoichiometric composition. That is, an excess-oxygen region is preferably formed in the insulator 280.

In order to provide the excess-oxygen region in the insulator 280, oxygen (including at least oxygen radicals, oxygen atoms, or oxygen ions) is introduced into the insulator 280, whereby a region containing oxygen in excess is formed.

A method for stacking metal oxides over the insulator 280 using a sputtering apparatus is given as an example of the oxygen introduction treatment. For example, when the deposition in an oxygen gas atmosphere is performed using a sputtering apparatus as a means for depositing the insulator 282, oxygen can be introduced into the insulator 280 while the insulator 282 is deposited.

The insulator 280 functioning as an interlayer film preferably has a low permittivity. When a material with a low permittivity is used as an interlayer film, the parasitic capacitance generated between wirings can be reduced. The insulator 280 is preferably formed using a material similar to that used for the insulator 216, for example. In particular, silicon oxide and silicon oxynitride, which have thermal stability, are preferable. Materials such as silicon oxide, silicon oxynitride, and porous silicon oxide, in each of which a region containing oxygen released by heating can be easily formed, are particularly preferable.

The concentration of impurities such as water and hydrogen in the insulator 280 is preferably reduced. Moreover, the insulator 280 preferably has a low hydrogen concentration and includes an excess-oxygen region or excess oxygen, and may be formed using a material similar to that for the insulator 216, for example. Note that the insulator 280 may have a stacked-layer structure of two or more layers.

Like the insulator 214 and the like, the insulator 282 preferably functions as an insulating barrier film that inhibits diffusion of impurities such as water and hydrogen into the insulator 280 from above. In addition, like the insulator 214 and the like, the insulator 282 preferably has a low hydrogen concentration and has a function of inhibiting diffusion of hydrogen.

In particular, when silicon oxynitride is used as the insulator 280, aluminum oxide is preferably used as the insulator 282. When an aluminum oxide film is formed over a silicon oxynitride film by a sputtering method, an excess-oxygen region can be formed in silicon oxide, which is the object to be formed.

Aluminum oxide may have a function of inhibiting diffusion of oxygen. Compared to silicon oxynitride, in particular, aluminum oxide has a function of inhibiting diffusion of oxygen or impurities such as water or hydrogen.

Thus, when aluminum oxide is used as the insulator 282, impurities such as water or hydrogen can be inhibited from being diffused into the transistor 200 side from above the insulator 282.

As illustrated in FIG. 3B, the insulator 282 is preferably in contact with the top surfaces of the conductor 260, the insulator 250, and the oxide 230c. This can inhibit entry of impurities such as hydrogen contained in the insulator 284 and the like into the insulator 250. Thus, adverse effects on the electrical characteristics of the transistor and the reliability of the transistor can be inhibited.

The insulator 284 functioning as an interlayer film is preferably provided over the insulator 282. Like the insulator 216 or the like, the insulator 284 preferably has a low permittivity. As in the insulator 224 and the like, the concentration of impurities such as water and hydrogen in the insulator 284 is preferably reduced.

### <<Metal Oxide>>

For the oxide 230, a metal oxide functioning as an oxide semiconductor is preferably used. A metal oxide that can be used for the oxide 230 of the present invention is described below.

The metal oxide preferably contains at least indium or zinc. In particular, indium and zinc are preferably contained. Moreover, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide containing indium, the element M, and zinc is considered. Note that the element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, and magnesium. Note that it is sometimes acceptable to use a plurality of the above-described elements in combination as the element M.

Note that in this specification and the like, a metal oxide containing nitrogen is also referred to as a metal oxide in some cases. A metal oxide containing nitrogen may be referred to as a metal oxynitride.

### [Structure of Metal Oxide]

Oxide semiconductors (metal oxides) can be classified into a single crystal oxide semiconductor and a non-single-crystal oxide semiconductor. Examples of a non-single-crystal oxide semiconductor include a CAAC-OS, a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear crystal grain boundary (also referred to as grain boundary) even in the vicinity of distortion in the CAAC-OS. That is, formation of a crystal grain boundary is inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, an In layer) and a layer containing the element M, zinc, and oxygen (hereinafter, an (M, Zn) layer) are stacked. Note that indium and the element M can be replaced with each other, and when the element M in the (M, Zn) layer is replaced with indium, the layer can also be referred to as an (In, M, Zn) layer. Furthermore, when indium in the In layer is replaced with the element M, the layer can also be referred to as an (In, M) layer.

The CAAC-OS is a metal oxide with high crystallinity. By contrast, in the CAAC-OS, a reduction in electron mobility due to a crystal grain boundary is less likely to occur because it is difficult to observe a clear crystal grain boundary. Entry of impurities, formation of defects, or the like might decrease the crystallinity of a metal oxide, which means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that an In—Ga—Zn oxide (hereinafter, IGZO) that is a kind of metal oxide containing indium, gallium, and zinc has a stable structure in some cases by being formed of the above-described nanocrystals. In particular, crystals of IGZO tend not to grow in the air and thus, a stable structure is obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS contains a void or a low-density region. That is, the a-like OS has low crystallinity compared with the nc-OS and the CAAC-OS.

An oxide semiconductor (metal oxide) can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Impurity]

Here, the influence of each impurity in the metal oxide will be described.

Entry of the impurities into the oxide semiconductor forms defect states or oxygen vacancies in some cases. Thus, when impurities enter a channel formation region of the oxide semiconductor, the electrical characteristics of a transistor using the oxide semiconductor are likely to vary and its reliability is degraded in some cases. Moreover, when the channel formation region includes oxygen vacancies, the transistor tends to have normally-on characteristics.

The above-described defect states may include a trap state. Charges trapped by the trap states in the metal oxide take a long time to be released and may behave like fixed charges. Thus, a transistor whose channel formation region includes a metal oxide having a high density of trap states has unstable electrical characteristics in some cases.

If the impurities exist in the channel formation region of the oxide semiconductor, the crystallinity of the channel formation region may decrease, and the crystallinity of an oxide provided in contact with the channel formation region may decrease. Low crystallinity of the channel formation region tends to result in deterioration in stability or reliability of the transistor. Moreover, if the crystallinity of the oxide provided in contact with the channel formation region is low, an interface state may be formed and the stability or reliability of the transistor may deteriorate.

Therefore, the reduction in concentration of impurities in and around the channel formation region of the oxide semiconductor is effective in improving the stability or reliability of the transistor. Examples of impurities include hydrogen, nitrogen, an alkali metal, an alkaline earth metal, iron, nickel, and silicon.

Specifically, the concentration of the above impurities obtained by SIMS is lower than or equal to 1×10¹⁸ atoms/cm³, preferably lower than or equal to 2×10¹⁶ atoms/cm³ in and around the channel formation region of the oxide semiconductor. Alternatively, the concentration of the above impurities obtained by element analysis using EDX is lower than or equal to 1.0 atomic % in and around the channel formation region of the oxide semiconductor. When an oxide containing the element M is used as the oxide semiconductor, the concentration ratio of the impurities to the element M is lower than 0.10, preferably lower than 0.05 in and around the channel formation region of the oxide semiconductor. Here, the concentration of the element M used in the calculation of the concentration ratio may be a concentration in a region whose concertation of the impurities is calculated or may be a concentration in the oxide semiconductor.

A metal oxide with a low impurity concentration has a low density of defect states and thus has a low density of trap states in some cases.

In the case where hydrogen enters an oxygen vacancy in the metal oxide, the oxygen vacancy and the hydrogen are bonded to each other to form VoH in some cases. The VoH serves as a donor and an electron that is a carrier is generated in some cases. In other cases, bonding of part of hydrogen to oxygen bonded to a metal atom generates electrons serving as carriers.

Thus, a transistor including an oxide semiconductor which contains a large amount of hydrogen is likely to be normally on. Moreover, hydrogen in an oxide semiconductor is easily transferred by a stress such as heat or an electric field; thus, a large amount of hydrogen in an oxide semiconductor might reduce the reliability of a transistor.

Accordingly, the amount of VoH in the metal oxide is preferably reduced as much as possible so that the metal oxide becomes a highly purified intrinsic or substantially highly purified intrinsic metal oxide. In order to obtain such an oxide semiconductor with sufficiently reduced VoH, it is important to remove impurities such as moisture and hydrogen in the oxide semiconductor (this treatment is sometimes referred to as dehydration or dehydrogenation treatment) and supply oxygen to the oxide semiconductor to fill oxygen vacancies (this treatment is sometimes referred to as oxygen adding treatment). When an oxide semiconductor with sufficiently reduced impurities such as VoH is used for a channel formation region of a transistor, stable electrical characteristics can be given.

An oxide semiconductor with a low carrier concentration is preferably used for a transistor. In the case where the carrier concentration of the oxide semiconductor is lowered, the impurity concentration in the oxide semiconductor is lowered to decrease the density of defect states. In this specification and the like, a state with a low impurity concentration and a low density of defect states is referred to as a highly purified intrinsic or substantially highly purified intrinsic state. Examples of the impurities in the oxide semiconductor include hydrogen, nitrogen, alkali metal, alkaline earth metal, iron, nickel, and silicon.

In particular, hydrogen contained in an oxide semiconductor reacts with oxygen bonded to a metal atom to be water, and thus forms oxygen vacancies in the oxide semiconductor in some cases. If the channel formation region in the oxide semiconductor includes oxygen vacancies, the transistor sometimes has normally-on characteristics. In some cases, a defect that is an oxygen vacancy into which hydrogen enters functions as a donor and generates an electron serving as a carrier. In other cases, bonding of part of hydrogen to oxygen bonded to a metal atom generates electrons serving as carriers. Thus, a transistor including an oxide semiconductor which contains a large amount of hydrogen is likely to be normally on.

A defect in which hydrogen has entered an oxygen vacancy (VoH) can function as a donor of the oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” in this specification and the like can be replaced with “donor concentration” in some cases.

Thus, hydrogen in the oxide semiconductor is preferably reduced as much as possible. Specifically, the hydrogen concentration of the oxide semiconductor, which is measured by secondary ion mass spectrometry (SIMS), is lower than 1×10²⁰ atoms/cm³, preferably lower than 1×10¹⁹ atoms/cm³, more preferably lower than 5×10¹⁸ atoms/cm³, still more preferably lower than 1×10¹⁸ atoms/cm³. When an oxide semiconductor with a sufficiently low concentration of impurities such as hydrogen is used for a channel formation region of a transistor, the transistor can have stable electrical characteristics.

The carrier concentration of the oxide semiconductor in the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. Note that the lower limit of the carrier concentration of the oxide semiconductor in the channel formation region is not particularly limited and can be, for example, 1×10⁻⁹ cm⁻³.

According to one embodiment of the present invention, a semiconductor device with high reliability can be provided. According to another embodiment of the present invention, a semiconductor device having favorable electrical characteristics can be provided. According to another embodiment of the present invention, a semiconductor device with a high on-state current can be provided. According to another embodiment of the present invention, a semiconductor device that can be miniaturized or highly integrated can be provided. Another object of one embodiment of the present invention is to provide a semiconductor device with low power consumption.

### <Modification Example of Semiconductor Device>

An example of a semiconductor device including the transistor 200 of one embodiment of the present invention is described below using FIG. 4.

Here, (A) of FIG. 4 is a top view. FIG. 4B is a cross-sectional view corresponding to a portion indicated by the dashed-dotted line A1-A2 in FIG. 4A. FIG. 4C is a cross-sectional view corresponding to a portion indicated by the dashed-dotted line A3-A4 in FIG. 4A. For clarity of the drawing, some components are not shown in the top view of FIG. 4A.

The semiconductor device shown in FIG. 4 is different from the semiconductor device shown in FIG. 3 in that the oxide 230b has a stacked-layer structure. It is also different in that the oxide 230c has a single-layer structure. It is also different in that an insulator 273 and an insulator 274 are included.

The oxide 230b may have a stacked-layer structure of two or more layers. For example, in FIG. 4, the first oxide of the oxide 230b and the second oxide of the oxide 230b over the first oxide of the oxide 230b are included.

Specifically, the second oxide of the oxide 230b is preferably provided between the first oxide of the oxide 230b and the conductor 240 (the conductor 240a and the conductor 240b) functioning as a source electrode and a drain electrode. In the structure, the second oxide of the oxide 230b preferably has a function of inhibiting passage of oxygen.

It is preferable to provide the second oxide of the oxide 230b having a function of inhibiting passage of oxygen between the first oxide of the oxide 230b and the conductor 240 which functions as the source electrode and the drain electrode, in which case the electrical resistance between the conductor 240 and the first oxide of the oxide 230b is reduced. Such a structure improves the electrical characteristics of the transistor 200 and the reliability of the transistor 200.

The conductor 240 and the first oxide of the oxide 230b are not in contact with each other, which inhibit the conductor 240 from absorbing oxygen in the first oxide of the oxide 230b. Preventing oxidation of the conductor 240 can inhibit the decrease in conductivity of the conductor 240.

A metal oxide containing the element M may be used as the second oxide of the oxide 230b. In particular, aluminum, gallium, yttrium, or tin is preferably used as the element M. The concentration of the element M in the second oxide of the oxide 230b is preferably higher than that of the first oxide of the oxide 230b. Alternatively, gallium oxide may be used as the second oxide of the oxide 230b. A metal oxide such as an In-M-Zn oxide may be used as the second oxide of the oxide 230b.

Specifically, the atomic ratio of the element M to In in the metal oxide used as the second oxide of the oxide 230b is preferably greater than the atomic ratio of the element M to In in the metal oxide used as the first oxide of the oxide 230b. The thickness of the second oxide of the oxide 230b is preferably within the range of 0.5 nm to 5 nm, further preferably within the range of 1 nm to 3 nm. The second oxide of the oxide 230b preferably has crystallinity. When the second oxide of the oxide 230b has crystallinity, release of oxygen in the first oxide of the oxide 230b can be reduced. When the second oxide of the oxide 230b has a hexagonal crystal structure, for example, release of oxygen from the first oxide of the oxide 230b can sometimes be inhibited.

Contact between the conductor 240 (the conductor 240a and the conductor 240b) and the oxide 230 may make oxygen in the oxide 230 diffuse into the conductor 240, resulting in oxidation of the conductor 240. It is highly probable that oxidation of the conductor 240 lowers the conductivity of the conductor 240. Note that diffusion of oxygen in the oxide 230 into the conductor 240 can be rephrased as absorption of oxygen in the oxide 230 by the conductor 240.

Oxygen in the oxide 230 (typically in the oxide 230b) diffuses into the conductor 240, whereby another layer may be formed between the conductor 240 and the oxide 230. The layer contains more oxygen than the conductor 240 does, and thus the layer presumably has an insulating property. In this case, the three-layer structure of the conductor 240, the layer, and the oxide 230 can be regarded as a three-layer structure formed of metal-insulator-semiconductor, which is referred to as an MIS (Metal-Insulator-Semiconductor) structure or a diode junction structure having an MIS structure as its main part in some cases.

The insulator 273 having a barrier property may be provided to cover the top surface of the conductor 240 and the side surfaces of the oxide 230a, the oxide 230b, and the conductor 240. Note that when the insulator 273 is provided, the insulator 245 is not necessarily provided.

For example, oxygen vacancies are formed in the region of the oxide 230 which overlaps with the conductor 240 by the introduction of the metal element of the conductor 240 or absorption of oxygen by the conductor 240. That is, the vicinity of the surface of the oxide 230 which is in contact with the conductor 240 can locally have a lower resistance. The region of the oxide 230 which overlaps with the conductor 240 becomes low resistant; this can increase the on-state current of the transistor 200.

By contrast, the excess oxygen included in the insulator 280 is diffused through the side surface of the region of the oxide 230 which overlaps with the conductor 240 to the oxide 230; thus, the local lower-resistance region which is formed in the region of the oxide 230 which overlaps with the conductor 240 can be reduced and the on-state current of the transistor 200 can be lowered.

When the insulator 273 is provided, the excess oxygen included in the insulator 280 can be inhibited from being supplied through the side surface of the region of the oxide 230 which overlaps with the conductor 240. On the other hand, the excess oxygen included in the insulator 280 can be supplied to the channel formation region of the oxide 230b through the oxide 230c. Thus, the lower-resistance region which is formed in the vicinity of the surface of the oxide 230 in contact with the conductor 240 is not reduced and the oxygen vacancies formed in the channel formation region of the oxide 230 are efficiently compensated.

When the insulator 224 has an excess-oxygen region, excess oxygen contained in the insulator 224 is diffused into the oxide 230b through the oxide 230a in the oxide 230. In other words, excess oxygen can be supplied from the oxide 230a side. Accordingly, the reduction of the lower-resistance region which is formed in the vicinity of the surface of the oxide 230 in contact with the conductor 240 can be inhibited, and the oxygen vacancies formed in the channel formation region of the oxide 230 can be compensated.

The insulator 273 is preferably an aluminum oxide film formed using a sputtering apparatus. When the aluminum oxide film is formed as the insulator 273 under an oxygen gas atmosphere, excess oxygen can be introduced into the insulator 224 while the insulator 273 is formed.

The insulator 274 may be provided over the insulator 273. Note that like the insulator 273, the insulator 274 preferably has a function of inhibiting diffusion of oxygen.

Specifically, coverage with the insulator 273 formed by a sputtering method is low. The insulator 274 is preferably formed by an ALD method. This is because an ALD method can form a film having excellent thickness uniformity and excellent step coverage, which is less likely to be influenced by the shape of an object.

Note that in <Modification example of semiconductor device>, the structure having the same functions as the components included in the semiconductor device described in <Structure example of semiconductor device> are denoted by the same reference numerals. Note that the materials described in detail in <Structure Example of Semiconductor Device> can also be used as constituent materials of the semiconductor devices in this section.

According to the above, a semiconductor device with high reliability can be provided. In addition, a semiconductor device having favorable electrical characteristics can be provided. Furthermore, a semiconductor device that can be miniaturized or highly integrated can be provided. In addition, a semiconductor device with low power consumption can be provided.

The structure, method, and the like described above in this embodiment can be used in an appropriate combination with the structures, the methods, and the like described in the other embodiments and examples.

### Embodiment 2

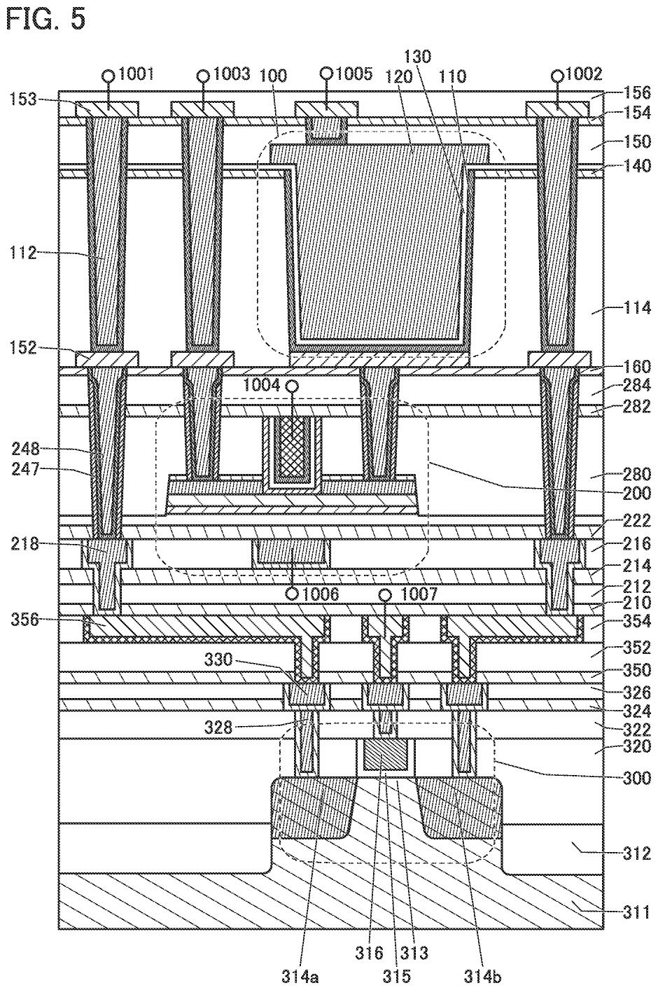

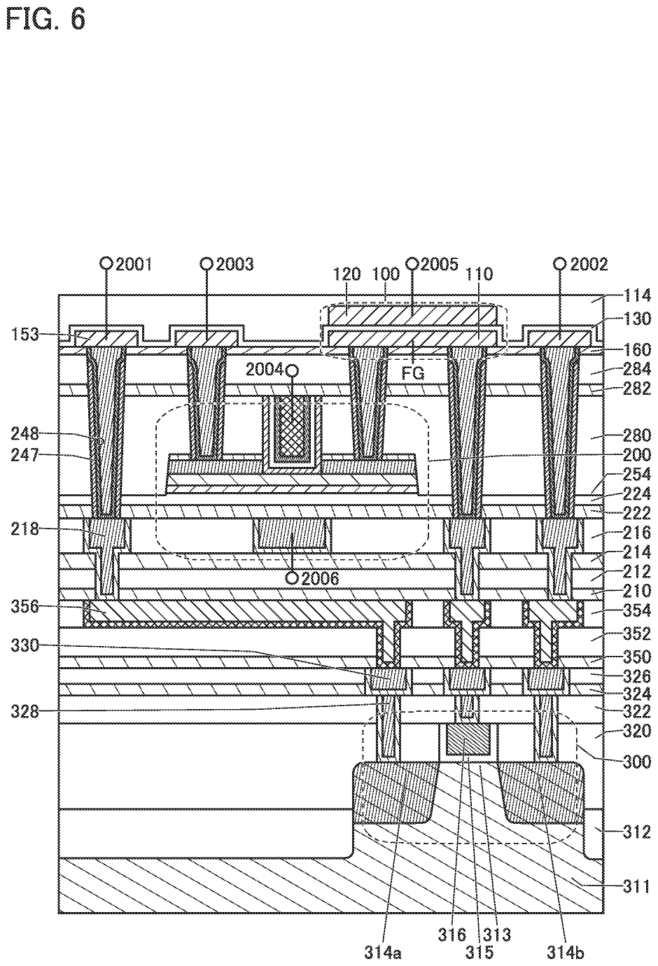

In this embodiment, one embodiment of a semiconductor device is described with reference to FIG. 5 and FIG. 6.

### [Memory Device 1]

FIG. 5 illustrates an example of a semiconductor device (memory device) in which a capacitor of one embodiment of the present invention is used. In the semiconductor device of one embodiment of the present invention, the transistor 200 is provided above a transistor 300, and a capacitor 100 is provided above the transistor 200. At least part of the capacitor 100 or the transistor 300 preferably overlaps with the transistor 200. Accordingly, an area occupied by the capacitor 100, the transistor 200, and the transistor 300 in a top view can be reduced, whereby the semiconductor device of this embodiment can be miniaturized or highly integrated. The semiconductor device of this embodiment can be applied to logic circuits typified by a CPU (Central Processing Unit) and a GPU (Graphics Processing Unit) and memory circuits typified by a DRAM (Dynamic Random Access Memory) and an NVM (Non-Volatile Memory), for example.

The transistor 200 described in the above embodiment can be used as the transistor 200. Therefore, for the transistor 200 and layers including the transistor 200, the description in the above embodiment can be referred to.

The transistor 200 is a transistor whose channel is formed in a semiconductor layer containing an oxide semiconductor. Since the transistor 200 has a low off-state current, a memory device including the transistor 200 can retain stored data for a long time. In other words, such a memory device does not require refresh operation or has an extremely low frequency of the refresh operation, which leads to a sufficient reduction in power consumption of the memory device. The transistor 200 exhibits favorable electrical characteristics at high temperatures, in comparison with a transistor including silicon in a semiconductor layer. For example, the transistor 200 has favorable electrical characteristics even in the temperature range of 125° C. to 150° C. Moreover, the transistor 200 has an on/off ratio of 10 digits or larger in the temperature range of 125° C. to 150° C. In other words, in comparison with a transistor including silicon in a semiconductor layer, the transistor 200 excels in characteristics such as on-state current and frequency characteristics at higher temperatures.

In the semiconductor device illustrated in FIG. 5, a wiring 1001 is electrically connected to a source of the transistor 300, a wiring 1002 is electrically connected to a drain of the transistor 300, and a wiring 1007 is electrically connected to a gate of the transistor 300. A wiring 1003 is electrically connected to one of the source and the drain of the transistor 200, a wiring 1004 is electrically connected to the first gate of the transistor 200, and a wiring 1006 is electrically connected to the second gate of the transistor 200. The other of the source and the drain of the transistor 200 is electrically connected to one electrode of the capacitor 100, and a wiring 1005 is electrically connected to the other electrode of the capacitor 100.

The semiconductor device illustrated in FIG. 5 has characteristics of being capable of retaining charge stored in the one electrode of the capacitor 100 by switching of the transistor 200; thus, writing, retention, and reading of data can be performed. The transistor 200 is an element in which a back gate is provided in addition to the source, the gate (top gate), and the drain. That is, the transistor 200 is a four-terminal element; hence, its input and output can be controlled independently of each other in a simpler manner than that in two-terminal elements typified by MRAM (Magnetoresistive Random Access Memory) utilizing MTJ (Magnetic Tunnel Junction) properties, ReRAM (Resistive Random Access Memory), and phase-change memory. In addition, the structure of MRAM, ReRAM, and phase-change memory may change at the atomic level when data is rewritten. By contrast, in the semiconductor device illustrated in FIG. 5, data rewriting is performed by charging or discharging of electrons with the transistor and the capacitor; thus, the semiconductor device has characteristics such as high write endurance and a few structure changes.

Furthermore, by arranging the semiconductor devices illustrated in FIG. 5 in a matrix, a memory cell array can be formed. In this case, the transistor 300 can be used for a read circuit, a driver circuit, or the like that is connected to the memory cell array. As described above, the semiconductor device illustrated in FIG. 5 constitutes the memory cell array. When the semiconductor device in FIG. 5 is used as a memory element, for example, an operating frequency of 200 MHz or higher is achieved at a driving voltage of 2.5 V and an evaluation environment temperature ranging from −40° C. to 85° C.

### <Transistor 300>

The transistor 300 is provided on a substrate 311 and includes a conductor 316 functioning as a gate electrode, an insulator 315 functioning as a gate insulator, a semiconductor region 313 that is part of the substrate 311, and a low-resistance region 314a and a low-resistance region 314b functioning as a source region and a drain region.

Here, the insulator 315 is placed over the semiconductor region 313, and the conductor 316 is placed over the insulator 315. The transistors 300 formed in the same layer are electrically isolated from one another by an insulator 312 functioning as an element isolation insulating layer. The insulator 312 can be formed using an insulator similar to an insulator 326 or the like described later. The transistor 300 may be a p-channel transistor or an n-channel transistor.

In the substrate 311, a region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be an HEMT (High Electron Mobility Transistor) using GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

The conductor 316 functioning as the gate electrode can be formed using a semiconductor material such as silicon containing an element that imparts n-type conductivity, such as arsenic or phosphorus, or an element that imparts p-type conductivity, such as boron, or using a conductive material such as a metal material, an alloy material, or a metal oxide material.

Note that the work function depends on a material of the conductor; thus, the threshold voltage can be adjusted by changing the material of the conductor. Specifically, it is preferable to use a material such as titanium nitride or tantalum nitride for the conductor. Moreover, in order to obtain both conductivity and embeddability, it is preferable to use stacked layers of metal materials such as tungsten and aluminum for the conductor, and it is particularly preferable to use tungsten in terms of heat resistance.

Here, in the transistor 300 illustrated in FIG. 5, the semiconductor region 313 (part of the substrate 311) in which the channel is formed has a convex shape. Furthermore, the conductor 316 is provided so as to cover a side surface and the top surface of the semiconductor region 313 with the insulator 315 positioned therebetween. Such a transistor 300 is also referred to as a FIN-type transistor because it utilizes a convex portion of the semiconductor substrate. Note that an insulator functioning as a mask for forming the convex portion may be placed in contact with an upper portion of the convex portion. Furthermore, although the case where the convex portion is formed by processing part of the semiconductor substrate is described here, a semiconductor film having a convex shape may be formed by processing an SOI substrate.

Note that the transistor 300 illustrated in FIG. 5 is an example and the structure is not limited thereto; an appropriate transistor is used in accordance with a circuit structure or a driving method.

As illustrated in FIG. 5, the semiconductor device includes a stack of the transistor 300 and the transistor 200. For example, the transistor 300 can be formed using a silicon-based semiconductor material, and the transistor 200 can be formed using an oxide semiconductor. That is, in the semiconductor device in FIG. 5, a silicon-based semiconductor material and an oxide semiconductor can be used in different layers. The semiconductor device illustrated in FIG. 5 can be manufactured in a process similar to that employing a manufacturing apparatus that is used in the case of a silicon-based semiconductor material, and can be highly integrated.

### <Capacitor>

The capacitor 100 includes an insulator 114 over an insulator 160, an insulator 140 over the insulator 114, a conductor 110 positioned in an opening formed in the insulator 114 and the insulator 140, an insulator 130 over the conductor 110 and the insulator 140, a conductor 120 over the insulator 130, and an insulator 150 over the conductor 120 and the insulator 130. Here, at least parts of the conductor 110, the insulator 130, and the conductor 120 are positioned in the opening formed in the insulator 114 and the insulator 140.

The conductor 110 functions as a lower electrode of the capacitor 100, the conductor 120 functions as an upper electrode of the capacitor 100, and the insulator 130 functions as a dielectric of the capacitor 100. The capacitor 100 has a structure in which the upper electrode and the lower electrode face each other with the dielectric positioned therebetween on a side surface as well as the bottom surface of the opening in the insulator 114 and the insulator 140; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used for the insulator 280 can be used for the insulator 114 and the insulator 150. The insulator 140 preferably functions as an etching stopper at the time of forming the opening in the insulator 114 and is formed using an insulator that can be used for the insulator 214.

The shape of the opening formed in the insulator 114 and the insulator 140 when seen from above may be a quadrangular shape, a polygonal shape other than a quadrangular shape, a polygonal shape with rounded corners, or a circular shape including an elliptical shape. Here, the area where the opening and the transistor 200 overlap with each other is preferably large in the top view. Such a structure can reduce the area occupied by the semiconductor device including the capacitor 100 and the transistor 200.

The conductor 110 is provided in contact with the opening formed in the insulator 140 and the insulator 114. The top surface of the conductor 110 is preferably substantially level with the top surface of the insulator 140. A conductor 152 provided over the insulator 160 is in contact with the bottom surface of the conductor 110. The conductor 110 is preferably deposited by an ALD method, a CVD method, or the like; for example, a conductor that can be used for the conductor 205 is used.

The insulator 130 is positioned to cover the conductor 110 and the insulator 140. The insulator 130 is preferably deposited by an ALD method or a CVD method, for example. The insulator 130 can be provided to have stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 130, an insulating film in which zirconium oxide, aluminum oxide, and zirconium oxide are stacked in this order can be used, for example.

For the insulator 130, a material with high dielectric strength, such as silicon oxynitride, or a high dielectric constant (high-k) material is preferably used. Alternatively, a stacked-layer structure using a material with high dielectric strength and a high dielectric constant (high-k) material may be employed.

As an insulator of a high dielectric constant (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, and the like can be given. The use of such a high-k material can ensure sufficient capacitance of the capacitor 100 even when the insulator 130 has a large thickness. When the insulator 130 has a large thickness, leakage current generated between the conductor 110 and the conductor 120 can be inhibited.

Examples of the material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which silicon nitride (SiNₓ) deposited by an ALD method, silicon oxide (SiOₓ) deposited by a PEALD method, and silicon nitride (SiNₓ) deposited by an ALD method are stacked in this order. The use of such an insulator with high dielectric strength can increase the dielectric strength and inhibit electrostatic breakdown of the capacitor 100.

The conductor 120 is positioned to fill the opening formed in the insulator 140 and the insulator 114. The conductor 120 is electrically connected to the wiring 1005 through a conductor 112 and a conductor 153. The conductor 120 is preferably deposited by an ALD method, a CVD method, or the like and is formed using a conductor that can be used for the conductor 205, for example.

Since the transistor 200 has a structure in which an oxide semiconductor is used, the transistor 200 is highly compatible with the capacitor 100. Specifically, since the transistor 200 containing an oxide semiconductor has a low off-state current, a combination of the transistor 200 and the capacitor 100 enables stored data to be retained for a long time.

### <Wiring Layers>

Wiring layers provided with an interlayer film, a wiring, a plug, and the like may be provided between the structure bodies. A plurality of wiring layers can be provided in accordance with the design. Note that a plurality of conductors functioning as plugs or wirings are collectively denoted by the same reference numeral in some cases. Furthermore, in this specification and the like, a wiring and a plug electrically connected to the wiring may be a single component. That is, there are a case where part of a conductor functions as a wiring and a case where part of a conductor functions as a plug.

For example, an insulator 320, an insulator 322, an insulator 324, and the insulator 326 are stacked over the transistor 300 in this order as interlayer films. Moreover, a conductor 328, a conductor 330, and the like that are electrically connected to the conductor 153 functioning as a terminal are embedded in the insulator 320, the insulator 322, the insulator 324, and the insulator 326. Note that the conductor 328 and the conductor 330 function as plugs or wirings.

The insulator functioning as an interlayer film may function as a planarization film that covers an uneven shape thereunder. For example, a top surface of the insulator 322 may be planarized by planarization treatment using a chemical mechanical polishing (CMP) method or the like to improve planarity.

A wiring layer may be provided over the insulator 326 and the conductor 330. For example, in FIG. 5, an insulator 350, an insulator 352, and an insulator 354 are provided to be stacked in this order. Furthermore, a conductor 356 is formed in the insulator 350, the insulator 352, and the insulator 354. The conductor 356 functions as a plug or a wiring.

An insulator 210, an insulator 212, the insulator 214, and the insulator 216 are stacked in this order over the insulator 354 and the conductor 356. A conductor 218, a conductor (the conductor 205) included in the transistor 200, and the like are embedded in the insulator 210, the insulator 212, the insulator 214, and the insulator 216. Note that the conductor 218 functions as a plug or a wiring that is electrically connected to the transistor 300.

The conductor 112, conductors (the conductor 120 and the conductor 110) included in the capacitor 100, and the like are embedded in the insulator 114, the insulator 140, the insulator 130, the insulator 150, and an insulator 154. Note that the conductor 112 functions as a plug or a wiring that electrically connects the capacitor 100, the transistor 200, or the transistor 300 to the conductor 153 functioning as a terminal.

The conductor 153 is provided over the insulator 154, and the conductor 153 is covered with an insulator 156. Here, the conductor 153 is in contact with a top surface of the conductor 112 and functions as a terminal of the capacitor 100, the transistor 200, or the transistor 300.

Examples of an insulator that can be used for an interlayer film include an oxide, a nitride, an oxynitride, a nitride oxide, a metal oxide, a metal oxynitride, and a metal nitride oxide, each of which has an insulating property. For example, when a material with a low relative permittivity is used for the insulator functioning as an interlayer film, the parasitic capacitance generated between wirings can be reduced. Accordingly, a material is preferably selected depending on the function of an insulator.

For example, for the insulator 320, the insulator 322, the insulator 326, the insulator 352, the insulator 354, the insulator 212, the insulator 114, the insulator 150, the insulator 156, and the like, an insulator with low relative permittivity is preferably used. For example, the insulators each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulators each preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

It is preferable that the resistivity of an insulator provided over or under the conductor 152 or the conductor 153 be higher than or equal to 1.0×10¹² Ωcm and lower than or equal to 1.0×10¹⁵ Ωcm, preferably higher than or equal to 5.0×10¹² Ωcm and lower than or equal to 1.0×10¹⁴ Ωcm, further preferably higher than or equal to 1.0×10¹³ Ωcm and lower than or equal to 5.0×10¹³ Ωcm. The resistivity of the insulator provided over or under the conductor 152 or the conductor 153 is preferably within the above range because the insulator can disperse charges accumulated between the transistor 200, the transistor 300, the capacitor 100, and wirings such as the conductor 152 while maintaining the insulating property, and thus, poor characteristics and electrostatic breakdown of the transistor and the semiconductor device including the transistor due to the charges can be inhibited. For such an insulator, silicon nitride or silicon nitride oxide can be used. For example, the resistivity of the insulator 160 or the insulator 154 can be set within the above range.

When a transistor using an oxide semiconductor is surrounded by insulators having a function of inhibiting passage of oxygen and impurities such as hydrogen, the electrical characteristics of the transistor can be stable. Thus, an insulator having a function of inhibiting passage of oxygen and impurities such as hydrogen is used for the insulator 324, the insulator 350, the insulator 210, and like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride can be used.

As the conductors that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, the conductor 152, the conductor 153, and the like, a single layer or stacked layers of a conductive material such as a metal material, an alloy material, a metal nitride material, a metal oxide material, and the like that are formed using the above materials can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

<Wiring or Plug in Layer Provided with Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, the insulator 247 is preferably provided between the insulator 280 containing excess oxygen and the conductor 248 in FIG. 5. Since the insulator 247 is provided in contact with the insulator 282, the conductor 248 and the transistor 200 can be sealed by the insulators having a barrier property.

That is, the excess oxygen contained in the insulator 280 can be inhibited from being absorbed by the conductor 248 when the insulator 247 is provided. In addition, by including the insulator 247, the diffusion of hydrogen, which is an impurity, into the transistor 200 through the conductor 248 can be inhibited.

Here, the conductor 248 functions as a plug or a wiring that is electrically connected to the transistor 200 or the transistor 300.

Specifically, the insulator 247 is provided in contact with a side wall of the opening in the insulator 284, the insulator 282, and the insulator 280, and the conductor 248 is formed in contact with its side surface. The conductor 240 is located on at least part of the bottom portion of the opening, and the conductor 248 is in contact with the conductor 240.

The conductor 248 is preferably formed using a conductive material containing tungsten, copper, or aluminum as its main component. In addition, the conductor 248 may have a stacked-layer structure. Although the transistor 200 having a structure in which the conductor 248 have a stacked-layer structure of two layers is illustrated, the present invention is not limited thereto. For example, the conductor 248 may be provided as a single layer or to have a stacked-layer structure of three or more layers.

In the case where the conductor 248 has a stacked-layer structure, a conductive material having a function of inhibiting passage of impurities such as water and hydrogen is preferably used as a conductor that is in contact with the conductor 240 and in contact with the insulator 280, the insulator 282, and the insulator 284 with the insulator 247 therebetween. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. The use of the conductive material can prevent oxygen added to the insulator 280 from being absorbed by the conductor 248. Moreover, impurities such as water and hydrogen contained in a layer above the insulator 284 can be inhibited from diffusing into the oxide 230 through the conductor 248.

As the insulator 247, for example, an insulator that can be used as the insulator 214, or the like may be used. The insulator 247 can inhibit diffusion of impurities such as water and hydrogen contained in the insulator 280 and the like into the oxide 230 through the conductor 248. In addition, oxygen contained in the insulator 280 can be prevented from being absorbed by the conductor 248.

Although not illustrated, the conductor 152 functioning as a wiring may be placed in contact with the top surface of the conductor 248. For the conductor functioning as a wiring, a conductive material containing tungsten, copper, or aluminum as its main component is preferably used. Furthermore, the conductor may have a stacked-layer structure and may be a stack of titanium or titanium nitride and any of the above conductive materials, for example. Note that the conductor may be formed to be embedded in an opening provided in an insulator.

The above is the description of the structure example. With the use of this structure, a semiconductor device using a transistor including an oxide semiconductor can be miniaturized or highly integrated. Alternatively, a change in electrical characteristics can be inhibited and reliability can be improved in a semiconductor device using a transistor including an oxide semiconductor. Alternatively, a transistor including an oxide semiconductor and having a high on-state current can be provided. Alternatively, a transistor including an oxide semiconductor and having a low off-state current can be provided. Alternatively, a semiconductor device with low power consumption can be provided.

### [Memory Device 2]

FIG. 6 illustrates an example of a semiconductor device (memory device) using the semiconductor device of one embodiment of the present invention. Like the semiconductor device illustrated in FIG. 5, the semiconductor device illustrated in FIG. 6 includes the transistor 200, the transistor 300, and the capacitor 100. Note that the semiconductor device illustrated in FIG. 6 differs from the semiconductor device illustrated in FIG. 5 in that the capacitor 100 is a planar capacitor and that the transistor 200 is electrically connected to the transistor 300.

In the semiconductor device of one embodiment of the present invention, the transistor 200 is provided above the transistor 300, and the capacitor 100 is provided above the transistor 300 and the transistor 200. At least part of the capacitor 100 or the transistor 300 preferably overlaps with the transistor 200. Accordingly, an area occupied by the capacitor 100, the transistor 200, and the transistor 300 in a top view can be reduced, whereby the semiconductor device of this embodiment can be miniaturized or highly integrated.

Note that the transistor 200 and the transistor 300 mentioned above can be used as the transistor 200 and the transistor 300, respectively. Therefore, the above description can be referred to for the transistor 200, the transistor 300, and the layers including them.

In the semiconductor device illustrated in FIG. 6, a wiring 2001 is electrically connected to the source of the transistor 300, and a wiring 2002 is electrically connected to the drain of the transistor 300. A wiring 2003 is electrically connected to one of the source and the drain of the transistor 200, a wiring 2004 is electrically connected to the first gate of the transistor 200, and a wiring 2006 is electrically connected to the second gate of the transistor 200. The gate of the transistor 300 and the other of the source and the drain of the transistor 200 are electrically connected to one electrode of the capacitor 100, and a wiring 2005 is electrically connected to the other electrode of the capacitor 100. Note that a node where the gate of the transistor 300, the other of the source and the drain of the transistor 200, and the one electrode of the capacitor 100 are connected to one another is hereinafter referred to as a node FG in some cases.

The semiconductor device illustrated in FIG. 6 is capable of retaining the potential of the gate of the transistor 300 (the node FG) by switching of the transistor 200; thus, data writing, retention, and reading can be performed.

By arranging the semiconductor devices illustrated in FIG. 6 in a matrix, a memory cell array can be formed.

The layer including the transistor 300 has the same structure as that in the semiconductor device illustrated in FIG. 5, and therefore, the above description can be referred to for the structure below the insulator 354.

The insulator 210, the insulator 212, the insulator 214, and the insulator 216 are positioned over the insulator 354. Here, an insulator having a function of inhibiting passage of oxygen and impurities such as hydrogen is used for the insulator 210, as for the insulator 350 and the like.

The conductor 218 is embedded in the insulator 210, the insulator 212, the insulator 214, and the insulator 216. The conductor 218 functions as a plug or a wiring that is electrically connected to the capacitor 100, the transistor 200, or the transistor 300. For example, the conductor 218 is electrically connected to the conductor 316 functioning as the gate electrode of the transistor 300.

Note that the conductor 248 functions as a plug or a wiring that is electrically connected to the transistor 200 or the transistor 300. For example, the conductor 248 electrically connects the conductor 240b functioning as the other of the source and the drain of the transistor 200 and the conductor 110 functioning as one electrode of the capacitor 100 through the conductor 248.

The planar capacitor 100 is provided above the transistor 200. The capacitor 100 includes the conductor 110 functioning as a first electrode, the conductor 120 functioning as a second electrode, and the insulator 130 functioning as a dielectric. Note that as the conductor 110, the conductor 120, and the insulator 130, those described above in Memory device 1 can be used.

The conductor 153 and the conductor 110 are provided in contact with the top surface of the conductor 248. The conductor 153 is in contact with the top surface of the conductor 248 and functions as a terminal of the transistor 200 or the transistor 300.

The conductor 153 and the conductor 110 are covered with the insulator 130, and the conductor 120 is positioned to overlap with the conductor 110 with the insulator 130 therebetween. In addition, the insulator 114 is positioned over the conductor 120 and the insulator 130.

Although FIG. 6 illustrates an example in which a planar capacitor is used as the capacitor 100, the semiconductor device of this embodiment is not limited thereto. For example, the capacitor 100 may be a cylinder capacitor 100 like that illustrated in FIG. 5.

### [Memory Device 3]

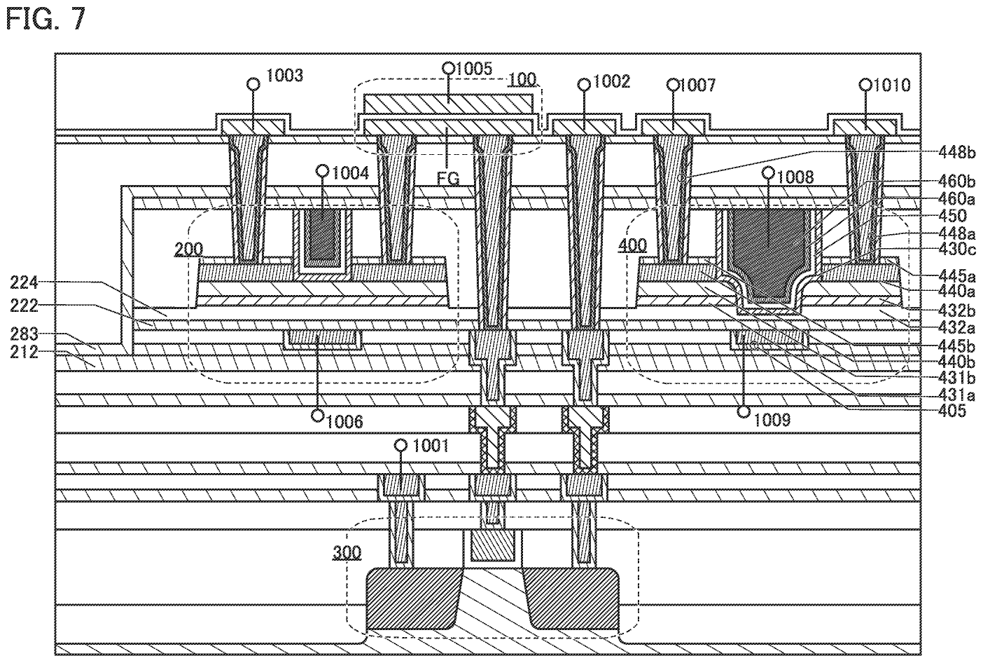

FIG. 7 illustrates an example of a memory device using the semiconductor device of one embodiment of the present invention. The memory device illustrated in FIG. 7 includes a transistor 400 in addition to the semiconductor device including the transistor 200, the transistor 300, and the capacitor 100 illustrated in FIG. 6.

The transistor 400 can control a second gate voltage of the transistor 200. For example, a first gate and a second gate of the transistor 400 are diode-connected to a source of the transistor 400, and the source of the transistor 400 is connected to the second gate of the transistor 200. When a negative potential of the second gate of the transistor 200 is retained in this structure, the first gate-source voltage and the second gate-source voltage of the transistor 400 become 0 V. In the transistor 400, a drain current at the time when a second gate voltage and a first gate voltage are 0 V is extremely low; thus, the negative potential of the second gate of the transistor 200 can be maintained for a long time even without power supply to the transistor 200 and the transistor 400. Accordingly, the memory device including the transistor 200 and the transistor 400 can retain stored data for a long time.

Hence, in FIG. 7, the wiring 1001 is electrically connected to the source of the transistor 300, and the wiring 1002 is electrically connected to the drain of the transistor 300. The wiring 1003 is electrically connected to one of the source and the drain of the transistor 200, the wiring 1004 is electrically connected to the gate of the transistor 200, and the wiring 1006 is electrically connected to a second gate (back gate) of the transistor 200. A gate of the transistor 300 and the other of the source and the drain of the transistor 200 are electrically connected to one electrode of the capacitor 100. The wiring 1005 is electrically connected to the other electrode of the capacitor 100. The wiring 1007 is electrically connected to the source of the transistor 400, a wiring 1008 is electrically connected to a gate of the transistor 400, a wiring 1009 is electrically connected to a second gate (back gate) of the transistor 400, and a wiring 1010 is electrically connected to the drain of the transistor 400. The wiring 1006, the wiring 1007, the wiring 1008, and the wiring 1009 are electrically connected to each other.

When the memory devices illustrated in FIG. 7 are arranged in a matrix like the memory devices illustrated in FIG. 5 and FIG. 6, a memory cell array can be formed. Note that one transistor 400 can control the second gate voltages of a plurality of transistors 200. For this reason, the number of transistors 400 is preferably smaller than the number of transistors 200.

### <Transistor 400>

The transistor 400 and the transistors 200 are formed in the same layer and thus can be fabricated in parallel. The transistor 400 includes a conductor 460 (a conductor 460a and a conductor 460b) functioning as a first gate electrode, a conductor 405 functioning as a second gate electrode, the insulator 222, the insulator 224, and an insulator 450 functioning as a gate insulating layer, an oxide 430c including a region where a channel is formed, a conductor 440a, an oxide 431a, and an oxide 431b functioning as one of a source and a drain, a conductor 440b, an oxide 432a, and an oxide 432b functioning as the other of the source and the drain, and an insulator 445a and an insulator 445b functioning as a barrier layer.

In the transistor 400, the conductor 405 is in the same layer as the conductor 205. The oxide 431a and the oxide 432a are in the same layer as the oxide 230a, and the oxide 431b and the oxide 432b are in the same layer as the oxide 230b. The conductor 440 (the conductor 440a and the conductor 440b) is in the same layer as the conductor 240. The insulator 445 (the insulator 445a and the insulator 445b) is in the same layer as the insulator 245. The oxide 430c is in the same layer as the oxide 230c. The insulator 450 is in the same layer as the insulator 250. The conductor 460 is in the same layer as the conductor 260.

Note that the components formed in the same layer can be formed at the same time. For example, the oxide 430c can be formed by processing an oxide film to be the oxide 230c.

In the oxide 430c functioning as an active layer of the transistor 400, oxygen vacancies and impurities such as hydrogen and water are reduced, as in the oxide 230 or the like. Accordingly, the threshold voltage of the transistor 400 can be higher than 0 V, the off-state current can be reduced, and the drain current at the time when the second gate voltage and the first gate voltage are 0 V can be extremely low.

This embodiment can be implemented in an appropriate combination with the structures described in the other embodiments, Example, and the like.

### Embodiment 3

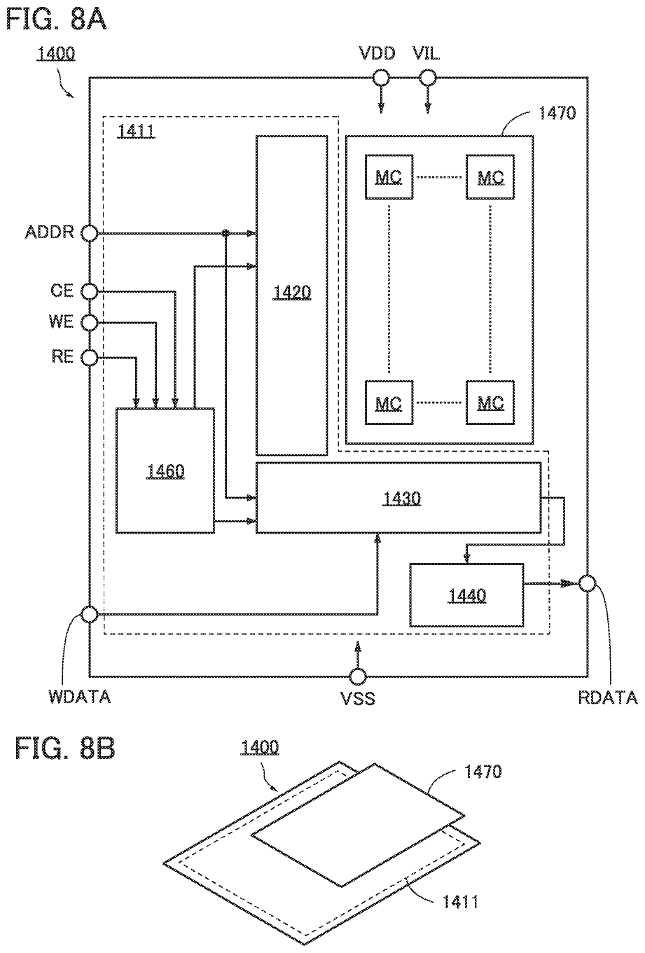

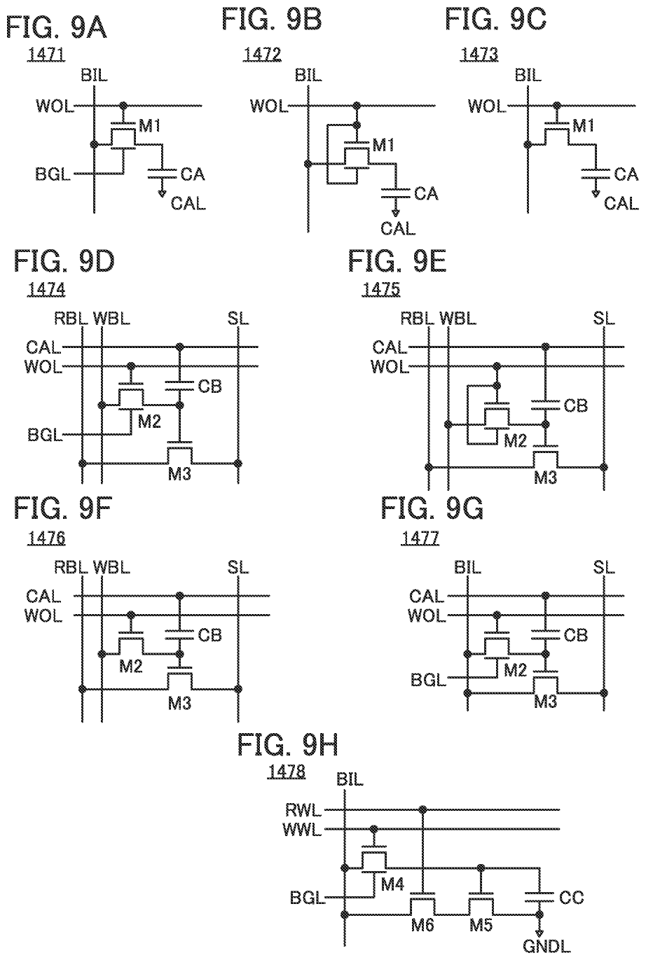

In this embodiment, a memory device of one embodiment of the present invention including a transistor in which oxide is used as a semiconductor (hereinafter referred to as an OS transistor in some cases) and a capacitor (hereinafter such a memory device is also referred to as an OS memory device in some cases) will be described with reference to FIG. 8 and FIG. 9. The OS memory device includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Memory Device>

FIG. 8A illustrates a structure example of the OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and will be described later in detail. The amplified data signal is output as a data signal RDATA to the outside of the memory device 1400 through the output circuit 1440. The row circuit 1420 includes, for example, a row decoder and a word line driver circuit, and can select a row to be accessed.

As power supply voltages from the outside, a low power supply voltage (VS S), a high power supply voltage (VDD) for the peripheral circuit 1411, and a high power supply voltage (VIL) for the memory cell array 1470 are supplied to the memory device 1400. Control signals (CE, WE, and RE), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the input signals (CE, WE, and RE) input from the outside, and generates control signals for the row decoder and the column decoder. CE is a chip enable signal, WE is a write enable signal, and RE is a read enable signal. Signals processed by the control logic circuit 1460 are not limited thereto, and other control signals may be input as necessary.

The memory cell array 1470 includes a plurality of memory cells MC arranged in a matrix and a plurality of wirings. Note that the number of the wirings that connect the memory cell array 1470 to the row circuit 1420 depends on the structure of the memory cell MC, the number of the memory cells MC in a column, and the like. The number of the wirings that connect the memory cell array 1470 to the column circuit 1430 depends on the structure of the memory cell MC, the number of the memory cells MC in a row, and the like.

Note that FIG. 8A shows an example in which the peripheral circuit 1411 and the memory cell array 1470 are formed on the same plane; however, this embodiment is not limited thereto. For example, as shown in FIG. 8B, the memory cell array 1470 may be provided over a part of the peripheral circuit 1411 so that they overlap. For example, the sense amplifier may be provided below the memory cell array 1470 so that they overlap with each other.

Structure examples of a memory cell in FIG. 9 that can be used in the memory cell MC are described.

### [DOSRAM]

FIG. 9A to FIG. 9C each illustrate a circuit structure example of a memory cell of a DRAM. In this specification and the like, a DRAM using a memory cell including one OS transistor and one capacitor is referred to as DOSRAM (Dynamic Oxide Semiconductor Random Access Memory) in some cases. A memory cell 1471 in FIG. 9A includes a transistor M1 and a capacitor CA. Note that the transistor M1 includes a gate (also referred to as a top gate in some cases) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In the time of data writing and data reading, a low-level potential is preferably applied to the wiring CAL. The wiring BGL functions as a wiring for applying a potential to the back gate of the transistor M1. Applying a given potential to the wiring BGL can increase or decrease the threshold voltage of the transistor M1.

Here, the memory cell 1471 shown in FIG. 9A corresponds to the memory device illustrated in FIG. 5. That is, the transistor M1, the capacitor CA, the wiring BIL, the wiring WOL, the wiring BGL, and the wiring CAL correspond to the transistor 200, the capacitor 100, the wiring 1003, the wiring 1004, the wiring 1006, and the wiring 1005, respectively. Note that the transistor 300 shown in FIG. 5 corresponds to a transistor provided in the peripheral circuit 1411 of the memory device 1400 illustrated in FIG. 8A and FIG. 8B.

The memory cell MC is not limited to the memory cell 1471, and the circuit structure can be changed. For example, like a memory cell 1472 in FIG. 9B, a structure may be used in which the back gate of the transistor M1 is connected not to the wiring BGL but to the wiring WOL in the memory cell MC. As another example, the memory cell MC may be configured with a single-gate transistor, that is, the transistor M1 that does not have a back gate, like a memory cell 1473 in FIG. 9C.

In the case where the semiconductor device described in the above embodiments is used in the memory cell 1471 and the like, the transistor 200 can be used as the transistor M1, and the capacitor 100 can be used as the capacitor CA. The use of an OS transistor as the transistor M1 enables the leakage current of the transistor M1 to be extremely low. That is, with the use of the transistor M1, written data can be retained for a long time, and thus the frequency of the refresh operation for the memory cell can be decreased, or the refresh operation of the memory cell can be omitted. Since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. Thus, the bit line capacitance can be small, and the storage capacitance of the memory cell can be reduced.

### [NOSRAM]

FIGS. 9D to 9G show circuit structure examples of a gain-cell type memory cell including two transistors and one capacitor. A memory cell 1474 shown in FIG. 9D includes a transistor M2, a transistor M3, and a capacitor CB. Note that the transistor M2 includes a front gate (simply referred to as a gate in some cases) and a back gate. In this specification and the like, a memory device including a gain-cell memory cell using an OS transistor as the transistor M2 is referred to as NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retaining, and data reading, a low-level potential is preferably applied to the wiring CAL. The wiring BGL functions as a wiring for applying a potential to the back gate of the transistor M2. By application of a given potential to the wiring BGL, the threshold voltage of the transistor M2 can be increased or decreased.

Here, the memory cell 1474 shown in FIG. 9D corresponds to the memory device shown in FIG. 6. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 2003, the wiring 2004, the wiring 2006, the wiring 2005, the wiring 2002, and the wiring 2001, respectively.

The memory cell MC is not limited to the memory cell 1474, and the circuit structure can be changed as appropriate. For example, like a memory cell 1475 in FIG. 9E, a structure may be used in which the back gate of the transistor M2 is connected not to the wiring BGL but to the wiring WOL in the memory cell MC. Alternatively, for example, like a memory cell 1476 in FIG. 9F, the memory cell MC may be a memory cell including a single-gate transistor, that is, the transistor M2 that does not include a back gate. For example, the memory cell MC may have a structure in which the wiring WBL and the wiring RBL are combined into one wiring BIL as in a memory cell 1477 in FIG. 9G.

In the case where the semiconductor device described in the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. That is, with the use of the transistor M2, written data can be retained for a long time, and thus the frequency of the refresh operation for the memory cell can be decreased. Alternatively, the refresh operation of the memory cell can be omitted. In addition, since the transistor M2 has an extremely low leakage current, multi-level data or analog data can be retained in the memory cell 1474. The same applies to the memory cell 1475 to the memory cell 1477.

Note that the transistor M3 may be a transistor containing silicon in a channel formation region (hereinafter also referred to as a Si transistor in some cases). The conductivity type of the Si transistor may be of either an n-channel type or a p-channel type. The Si transistor has higher field-effect mobility than the OS transistor in some cases. Therefore, a Si transistor may be used as the transistor M3 functioning as a reading transistor. Furthermore, the transistor M2 can be provided to be stacked over the transistor M3 when a Si transistor is used as the transistor M3; therefore, the area occupied by the memory cell can be reduced, leading to high integration of the memory device.

The transistor M3 may be an OS transistor. When an OS transistor is used as each of the transistor M2 and the transistor M3, the circuit of the memory cell array 1470 can be formed using only n-channel transistors.

FIG. 9H shows an example of a gain-cell type memory cell including three transistors and one capacitor. A memory cell 1478 in FIG. 9H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor including a back gate that is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In that case, the circuit of the memory cell array 1470 can be configured using only n-channel transistors.

In the case where the semiconductor device described in the above embodiments is used in the memory cell 1478, the transistor 200 can be used as the transistor M4, the transistor 300 can be used as the transistor M5 and the transistor M6, and the capacitor 100 can be used as the capacitor CC. When an OS transistor is used as the transistor M4, the leakage current of the transistor M4 can be extremely low.

Note that the structures of the peripheral circuit 1411, the memory cell array 1470, and the like described in this embodiment are not limited to the above. Positions and functions of these circuits, wirings connected to the circuits, circuit elements, and the like can be changed, deleted, or added as needed.

The structure described in this embodiment can be used in an appropriate combination with the structures described in the other embodiments, example, and the like.

### Embodiment 4

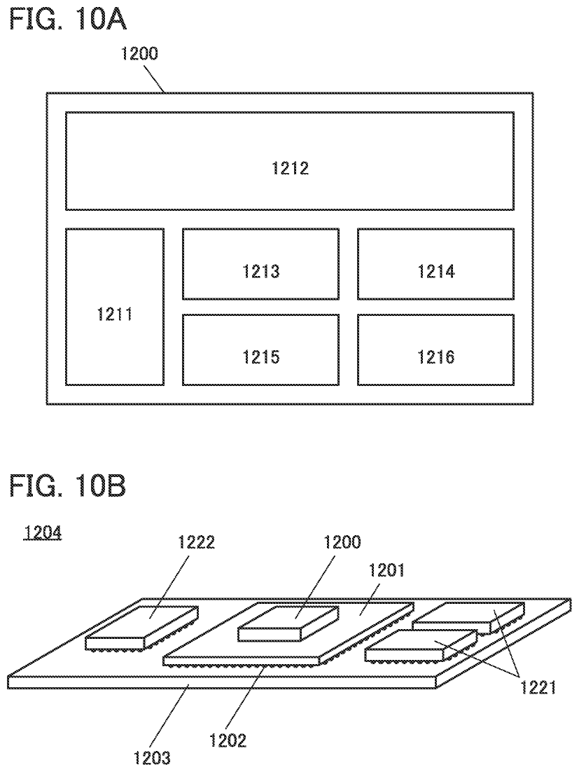

In this embodiment, an example of a chip 1200 on which a semiconductor device of the present invention is mounted is described using FIG. 10. A plurality of circuits (systems) are mounted on the chip 1200. The technique for integrating a plurality of circuits (systems) on one chip as described above is referred to as system on chip (SoC) in some cases.

As illustrated in FIG. 10A, the chip 1200 includes a CPU 1211, a GPU 1212, one or more of analog arithmetic units 1213, one or more of memory controllers 1214, one or more of interfaces 1215, one or more of network circuits 1216, and the like.

A bump (not illustrated) is provided on the chip 1200 and is connected to a first surface of a printed circuit board (PCB) 1201 as shown in FIG. 10B. A plurality of bumps 1202 are provided on the rear side of the first surface of the PCB 1201, and the PCB 1201 is connected to a motherboard 1203.

A memory device such as a DRAM 1221 or a flash memory 1222 may be provided over the motherboard 1203. For example, the DOSRAM described in the above embodiment can be used as the DRAM 1221. For example, the NOSRAM described in the above embodiment can be used as the flash memory 1222.

The CPU 1211 preferably includes a plurality of CPU cores. Furthermore, the GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The NOSRAM or the DOSRAM described above can be used as the memory. The GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

Since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. The analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, USB (Universal Serial Bus), HDMI (registered trademark) (High-Definition Multimedia Interface), or the like can be used.

The network circuit 1216 includes a circuit for a network such as a LAN (Local Area Network). The network circuit 1216 may include a circuit for network security.

The circuits (systems) can be formed in the chip 1200 in the same manufacturing process. Thus, even when the number of circuits needed for the chip 1200 is increased, there is no need to increase the number of steps in the manufacturing process; thus, the chip 1200 can be manufactured at low cost.

The motherboard 1203 provided with the PCB 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

The structure described in this embodiment can be used in an appropriate combination with the structures described in the other embodiments, example, and the like.

### Embodiment 5

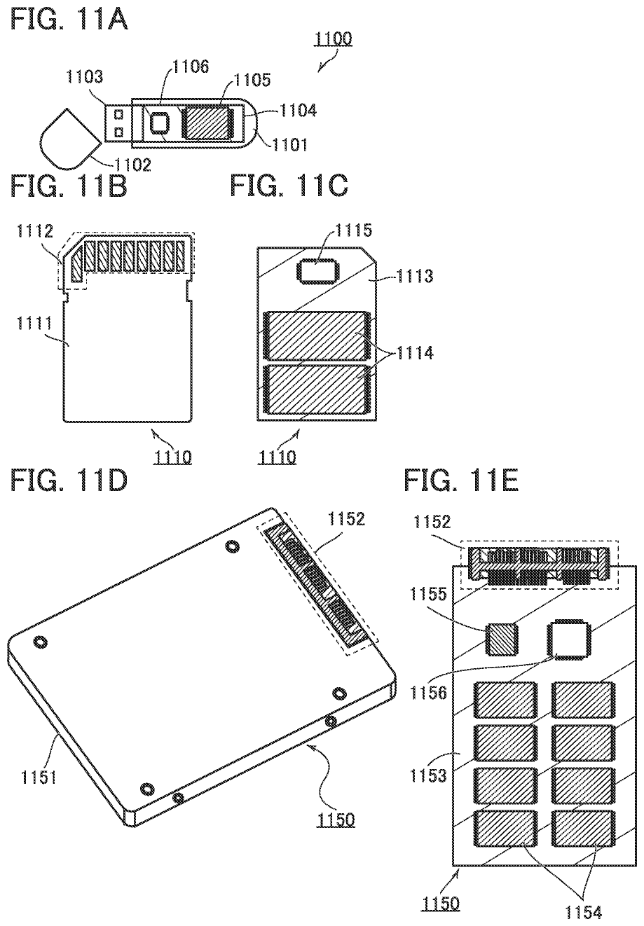

In this embodiment, application examples of the memory device using the semiconductor device described in the above embodiment are described. The semiconductor device described in the above embodiment can be applied to, for example, memory devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to removable memory devices such as memory cards (e.g., SD cards), USB memories, and SSDs (solid state drives). FIG. 11 schematically illustrates some structure examples of removable memory devices. The semiconductor device described in the above embodiment is processed into a packaged memory chip and used in a variety of storage devices and removable memories, for example.

FIG. 11A is a schematic view of a USB memory. A USB memory 1100 includes a housing 1101, a cap 1102, a USB connector 1103, and a substrate 1104. The substrate 1104 is held in the housing 1101. For example, a memory chip 1105 and a controller chip 1106 are attached to the substrate 1104. The semiconductor device described in the above embodiment can be incorporated in the memory chip 1105 or the like on the substrate 1104.

FIG. 11B is a schematic external view of an SD card, and FIG. 11C is a schematic view of the internal structure of the SD card. An SD card 1110 includes a housing 1111, a connector 1112, and a substrate 1113. The substrate 1113 is held in the housing 1111. For example, a memory chip 1114 and a controller chip 1115 are attached to the substrate 1113. When the memory chip 1114 is also provided on the rear surface side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114 or the like on the substrate 1113.

FIG. 11D is a schematic external view of an SSD, and FIG. 11E is a schematic view of the internal structure of the SSD. An SSD 1150 includes a housing 1151, a connector 1152, and a substrate 1153. The substrate 1153 is held in the housing 1151. For example, a memory chip 1154, a memory chip 1155, and a controller chip 1156 are attached to the substrate 1153. The memory chip 1155 is a work memory for the controller chip 1156, and a DOSRAM chip may be used, for example. When the memory chip 1154 is also provided on the rear surface side of the substrate 1153, the capacity of the SSD 1150 can be increased. The semiconductor device described in the above embodiment can be incorporated in the memory chip 1154 or the like on the substrate 1153.

This embodiment can be implemented in an appropriate combination with the structures described in the other embodiments, example, and the like.

### Embodiment 6

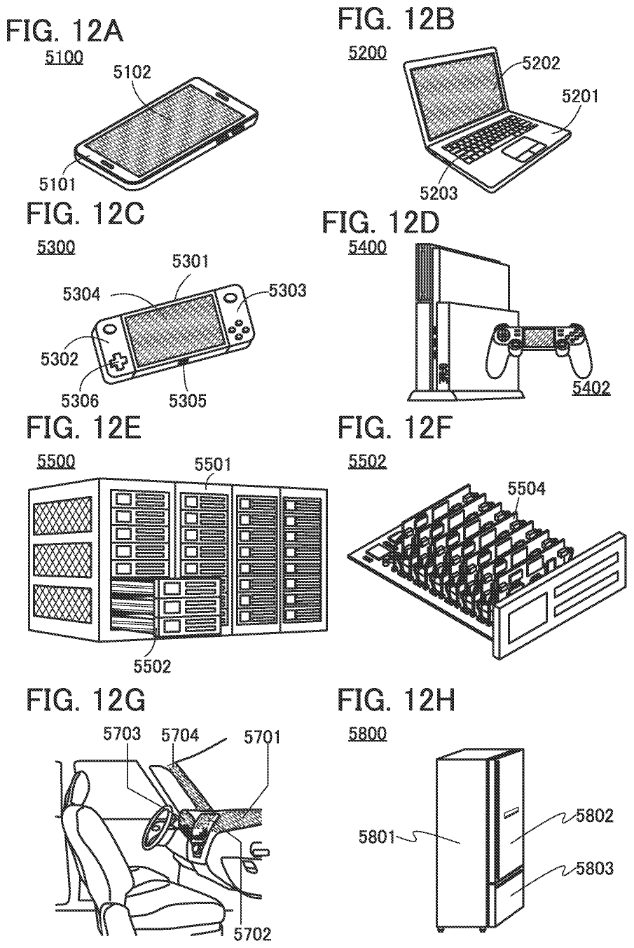

The semiconductor device of one embodiment of the present invention can be used as a processor such as a CPU and a GPU or a chip. FIG. 12 illustrates specific examples of electronic devices including processors such as CPUs and GPUs, or chips of one embodiment of the present invention.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. In addition, when the GPU or the chip of one embodiment of the present invention is provided in the electronic device, the electronic device can include artificial intelligence.

The electronic device of one embodiment of the present invention may include an antenna. When a signal is received by the antenna, a video, data, or the like can be displayed on the display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 12 illustrates examples of electronic devices.

### [Information Terminal]

FIG. 12A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 12B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with use of the notebook information terminal 5200, novel artificial intelligence can be developed.

Note that although FIG. 12A and FIG. 12B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 12C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not shown), an image to be output to the display portion 5304 can be output to another video device (not shown). In that case, the housing 5302 and the housing 5303 can each function as an operating unit. Thus, a plurality of players can perform a game at the same time. The chip described in the above embodiment can be incorporated into the chip provided on a substrate in the housing 5301, the housing 5302 and the housing 5303.

FIG. 12D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, questions posed by the player, the progress of the game, time, and actions and words of game characters can be changed for various expressions.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are shown as examples of game machines in FIG. 12C and FIG. 12D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 12E illustrates a supercomputer 5500 as an example of a large computer. FIG. 12F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip shown in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is shown as an example of a large computer in FIG. 12E and FIG. 12F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 12G illustrates an area around a windshield inside an automobile, which is an example of a moving vehicle. FIG. 12G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. The content, layout, or the like of the display on the display panels can be changed appropriately to suit the user's preferences, so that the design can be improved. The display panel 5701 to the display panel 5703 can also be used as lighting devices.

The display panel 5704 can compensate for view obstructed by the pillar (a blind spot) by showing an image taken by an imaging device (not shown) provided for the automobile. That is, displaying an image taken by the imaging device provided outside the automobile leads to compensation for the blind spot and an increase in safety. In addition, display of an image that complements the area that cannot be seen makes it possible to confirm safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. The display panel 5701 to the display panel 5704 may display information regarding navigation, risk prediction, and the like.

Although an automobile is described above as an example of a moving vehicle, moving vehicles are not limited to an automobile. Examples of a moving vehicle include a train, a monorail train, a ship, and a flying object (a helicopter, an unmanned aircraft (a drone), an airplane, and a rocket), and these moving vehicles can include a system utilizing artificial intelligence when equipped with the chip of one embodiment of the present invention.

### [Household Appliance]

FIG. 12H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be obtained. Utilizing the artificial intelligence enables the electric refrigerator-freezer 5800 to have a function of automatically making a menu based on foods stored in the electric refrigerator-freezer 5800 and the food expiration dates, for example, a function of automatically adjusting the temperature to be appropriate for the foods stored in the electric refrigerator-freezer 5800, and the like.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic device and the functions of the electronic device, the application example of the artificial intelligence and its effects, and the like described in this embodiment can be combined as appropriate with the description of another electronic device.

This embodiment can be implemented in an appropriate combination with the structures described in the other embodiments, example, and the like.

### Example 1

In this example, a semiconductor device including the transistor 200 including an oxide semiconductor was fabricated, and the thickness of an oxide film corresponding to the oxide 230c and the thickness of an oxidized portion of a conductor corresponding to the conductor 240 were measured.

Three kinds of the above semiconductor devices differ in the shape of a side end portion on the channel formation region side of the conductor corresponding to the conductor 240 were fabricated.

### <Manufacturing Method of Sample>

A method of fabricating the semiconductor device including the transistor 200 is described below.

First, as the first oxide corresponding to the oxide 230a, an In—Ga—Zn oxide was deposited by a sputtering method using a target with In:Ga:Zn=1:3:4 [atomic ratio]. Then, over the first oxide, an In—Ga—Zn oxide was deposited as a second oxide corresponding to the oxide 230b by a sputtering method using a target with In:Ga:Zn=4:2:4.1 [atomic ratio] and an In—Ga—Zn oxide was deposited by a sputtering method using a target with In:Ga:Zn=1:3:4 [atomic ratio], whereby a stacked-layer structure of two layers was formed. Note that the first oxide and the second oxide were successively deposited.

Next, over the second oxide, a tantalum nitride film was deposited as a film to be the conductor corresponding to the conductor 240.

After that, the tantalum nitride film, the second oxide, and the first oxide were processed to form the oxide 230a, the oxide 230b, and a tantalum nitride layer.

Next, an insulator corresponding to the insulator 280 was deposited, and the insulator was polished by CMP treatment so that a surface of the insulator was planarized.

Here, an opening portion was formed in the insulator corresponding to the insulator 280. Then, a conductive layer exposed on a bottom surface of the opening portion was partly removed to form the conductor corresponding to the conductor 240a and the conductor 240b.

Next, a film to be a third oxide corresponding to the oxide 230c was deposited as a stacked-layer structure of two layers. As a first film of the film to be the third oxide, an In—Ga—Zn oxide was deposited by a sputtering method using a target with In:Ga:Zn=4:2:4.1 [atomic ratio]; and as a second film of the film to be the third oxide, an In—Ga—Zn oxide was deposited by a sputtering method using a target with In:Ga:Zn=1:3:4 [atomic ratio].

Note that the target thickness, from the flat surface, of the first film of the film to be the third oxide was 8 nm. The target thickness, from the flat surface, of the second film of the film to be the third oxide was also 8 nm. Thus, the thickness of the film to be the third oxide was set to 16 nm.

Next, a silicon oxynitride film was deposited as a film to be an insulator corresponding to the insulator 250.

Next, a film to be a conductor corresponding to the conductor 260a and a film to be a conductor corresponding to the conductor 260b were deposited over the silicon oxynitride film to be the insulator 250.

Then, the film to be the conductor corresponding to the conductor 260a, the film to be the conductor corresponding to the conductor 260b, the film to be the insulator corresponding to the insulator 250, and the film to be the third oxide corresponding to the oxide 230c were removed, whereby the conductor corresponding to the conductor 260, the insulator corresponding to the insulator 250, and the oxide corresponding to the oxide 230c were formed.

Through the above process, the semiconductor device including the transistor 200 including an oxide semiconductor was fabricated.

### <Thickness of Oxidized Portion of Side End Portion of Conductor 240>

In the fabricated semiconductor devices, the thickness of a region where the oxide corresponding to the oxide 230c was in contact with a side surface of the conductor corresponding to the conductor 240b and the thickness of an oxidized portion of the conductor 240b in the region were measured.

Note that the measurement was performed with a scanning transmission electron microscope (STEM). As an apparatus for the observation, HD-2700 manufactured by Hitachi High-Technologies Corporation was used.

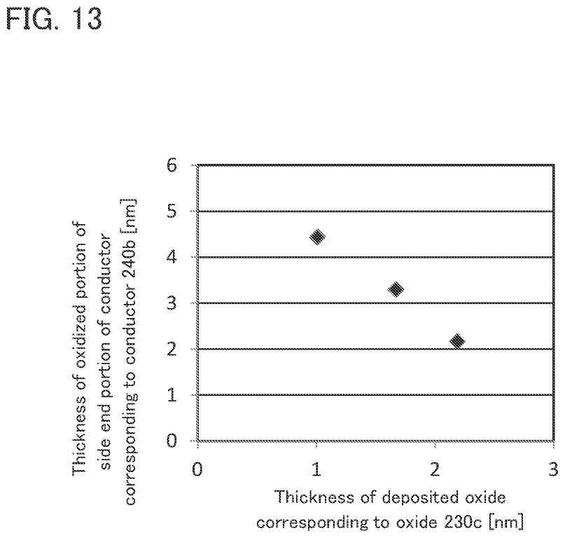

FIG. 13 shows the relationship between the thickness of the actually deposited oxide corresponding to the oxide 230c (the thickness of the deposited oxide corresponding to the oxide 230c) and the thickness of a portion where a side end portion of the conductor corresponding to the conductor 240b is oxidized (the thickness of the oxidized portion of the side end portion of the conductor corresponding to the conductor 240b).

FIG. 13 reveals that coverages depend on the shapes of the object to be formed even when the films corresponding to the oxide 230c were deposited under the same conditions. It is also found that the amount of the oxide of the film corresponding to the conductor 240b increases as the coverage with the oxide 230c is poorer.

At least part of this example can be implemented in combination with the other embodiments described in this specification as appropriate.

### REFERENCE NUMERALS

100: capacitor, 110: conductor, 112: conductor, 114: insulator, 120: conductor, 130: insulator, 140: insulator, 150: insulator, 152: conductor, 153: conductor, 154: insulator, 156: insulator, 160: insulator, 200: transistor, 205: conductor, 210: insulator, 212: insulator, 214: insulator, 216: insulator, 218: conductor, 222: insulator, 224: insulator, 230: oxide, 230a: oxide, 230b: oxide, 230c: oxide, 230c_1: oxide, 230c_2: oxide, 239: region, 240: conductor, 240a: conductor, 240b: conductor, 245: insulator, 245a: insulator, 245b: insulator, 247: insulator, 248: conductor, 250: insulator, 260: conductor, 260a: conductor, 260b: conductor, 273: insulator, 274: insulator, 280: insulator, 282: insulator, 284: insulator, 300: transistor, 311: substrate, 312: insulator, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 400: transistor, 405: conductor, 405a: conductor, 405b: conductor, 430c: oxide, 431a: oxide, 431b: oxide, 432a: oxide, 432b: oxide, 440: conductor, 440a: conductor, 440b: conductor, 445: insulator, 445a: insulator, 445b: insulator, 450: insulator, 460: conductor, 460a: conductor, 460b: conductor, 1001: wiring, 1002: wiring, 1003: wiring, 1004: wiring, 1005: wiring, 1006: wiring, 1007: wiring, 1008: wiring, 1009: wiring, 1010: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: PCB, 1202: bump, 1203: motherboard, 1204: GPU module, 1211: CPU, 1212: GPU, 1213: analog arithmetic portion, 1214: memory controller, 1215: interface, 1216: network circuit, 1221: DRAM, 1222: flash memory, 1400: memory device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2001: wiring, 2002: wiring, 2003: wiring, 2004: wiring, 2005: wiring, 2006: wiring, 5100: information terminal, 5101: housing, 5102: display portion, 5200: laptop information terminal, 5201: main body, 5202: display portion, 5203: keyboard, 5300: portable game machine, 5301: housing, 5302: housing, 5303: housing, 5304: display portion, 5305: connection portion, 5306: control key, 5400: type game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising a first oxide, a second oxide, a first conductor, a second conductor, a third conductor, a first insulator, and a second insulator,
wherein the first conductor and the second conductor are provided over and in contact with the first oxide,
wherein the first insulator is provided to cover the first oxide, the first conductor, and the second conductor,
wherein the first insulator comprises an opening portion,
wherein the first oxide is exposed on a bottom surface of the opening portion,
wherein a side surface of the first conductor and a side surface of the second conductor are exposed on a side surface of the opening portion,
wherein the second oxide is provided in contact with the first oxide, the side surface of the first conductor, and the second conductor in the opening portion,
wherein the second insulator is provided in the opening portion with the second oxide therebetween,
wherein the third conductor is provided in the opening portion with the second insulator therebetween, and
wherein lower end portions of the side surface of the first conductor and the second conductor touch an ellipse or a circle having a center above the first oxide.

2. A semiconductor device comprising a first oxide, a second oxide, a first conductor, a second conductor, a third conductor, a first insulator, and a second insulator,
wherein the first conductor and the second conductor are provided over and in contact with the first oxide,
wherein the first insulator is provided to cover the first oxide, the first conductor, and the second conductor,
wherein the first insulator comprises an opening portion,
wherein the first oxide is exposed on a bottom surface of the opening portion,
wherein a side surface of the first conductor and a side surface of the second conductor are exposed on a side surface of the opening portion,
wherein the second oxide is provided in contact with the first oxide, the side surface of the first conductor, and the second conductor in the opening portion,
wherein the second insulator is provided in the opening portion with the second oxide therebetween,
wherein the third conductor is provided in the opening portion with the second insulator therebetween,
wherein lower end portions of the side surface of the first conductor and the second conductor each comprise a side surface like an arc with a curvature center above the first oxide, and
wherein a length of a line perpendicular to the first oxide from the curvature center is substantially equal to a curvature radius of the arc.

3. The semiconductor device according to claim 2,
wherein a dihedral angle between a tangent plane touching the side surface like an arc at a termination portion of the side surface and a top surface of the first oxide is 0°<θθ90°.

4. The semiconductor device according to claim 2,
wherein an upper end portion of the side surface of the first conductor and an upper end portion of the side surface of the second conductor are each substantially aligned with the tangent plane touching the side surface like an arc at a termination portion of the side surface.

5. The semiconductor device according to claim 2,
wherein the curvature radius is greater than or equal to a total of a thickness of the second oxide and a thickness of the second insulator.

6. The semiconductor device according to claim 2,
wherein a horizontal distance L between the curvature center and a side that is formed by a bottom surface of the third conductor and a side surface of the third conductor is less than or equal to 0.

7. The semiconductor device according to claim 1,
wherein the second oxide has a higher barrier property against oxygen than the second insulator.

8. The semiconductor device according to claim 1,
wherein the first oxide is an In—Ga—Zn oxide.

9. The semiconductor device according to claim 1,
wherein the second oxide is an In—Ga—Zn oxide.

10. The semiconductor device according to claim 2,
wherein the second oxide has a higher barrier property against oxygen than the second insulator.

11. The semiconductor device according to claim 2,
wherein the first oxide is an In—Ga—Zn oxide.

12. The semiconductor device according to claim 2,
wherein the second oxide is an In—Ga—Zn oxide.

13. The semiconductor device according to claim 3,
wherein an upper end portion of the side surface of the first conductor and an upper end portion of the side surface of the second conductor are each substantially aligned with the tangent plane touching the side surface like an arc at the termination portion of the side surface.

14. The semiconductor device according to claim 3,
wherein the curvature radius is greater than or equal to a total of a thickness of the second oxide and a thickness of the second insulator.

15. The semiconductor device according to claim 4,
wherein the curvature radius is greater than or equal to a total of a thickness of the second oxide and a thickness of the second insulator.

16. The semiconductor device according to claim 3,
wherein a horizontal distance L between the curvature center and a side that is formed by a bottom surface of the third conductor and a side surface of the third conductor is less than or equal to 0.

17. The semiconductor device according to claim 4,
wherein a horizontal distance L between the curvature center and a side that is formed by a bottom surface of the third conductor and a side surface of the third conductor is less than or equal to 0.

18. The semiconductor device according to claim 5,
wherein a horizontal distance L between the curvature center and a side that is formed by a bottom surface of the third conductor and a side surface of the third conductor is less than or equal to 0.
